(19) United States
(12) Patent Application Publication
(10) Pub. No.: US 2025/0364044 A1
(43) Pub. Date: Nov. 27, 2025

(54) MEMORY DEVICES AND METHODS OF MANUFACTURING AND OPERATING THEREOF

(71) Applicant: Taiwan Semiconductor Manufacturing Company, Ltd., Hsinchu (TW)

(72) Inventors: Hung-Li Chiang, Taipei City (TW); Jen-Chieh Liu, Hsinchu City (TW); Jui-Jen Wu, Hsinchu City (TW); Meng-Fan Chang, Taichung City (TW); Jer-Fu Wang, Taipei City (TW); Iuliana Radu, Hsinchu City (TW)

(73) Assignee: Taiwan Semiconductor Manufacturing Company, Ltd., Hsinchu (TW)

(21) Appl. No.: 19/292,332

(22) Filed: Aug. 6, 2025

Related U.S. Application Data
(62) Division of application No. 18/103,664, filed on Jan. 31, 2023.

(51) Int. Cl. G11C 11/419; G11C 11/412; H01L 23/528; H10B 10/00

(52) U.S. Cl. CPC G11C 11/419; G11C 11/412; H01L 23/5283; H10B 10/125

(57) ABSTRACT

Memory devices and related methods are disclosed. A memory cell can include one or more first conduction channels extending along a first lateral direction, overlaid by a first gate structure and a parallel second gate structure, both extending along a second lateral direction. A second conduction channel can be disposed parallel to the first conduction channels. A third gate structure can overlay the second conduction channel. The device can further include a first interconnect structure extending along the second lateral direction, overlying both the first and second conduction channels, and a second interconnect structure extending along the second lateral direction and overlying only the first conduction channels.

### CROSS-REFERENCES TO RELATED APPLICATIONS

This application is a divisional of and claims priority to U.S. patent application Ser. No. 18/103,664, filed Jan. 31, 2023, the disclosure of which is incorporated herein by reference in its entirety for all purposes.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a circuit diagram of an example memory cell, in accordance with some embodiments.

FIG. 2 illustrates a circuit diagram of an example memory cell, in accordance with some embodiments.

FIGS. 3, 4, 5, and 6 illustrate layouts to form the memory cell of FIG. 1 or FIG. 2, in accordance with some embodiments.

FIGS. 7A to 7D illustrate operation statuses of the memory cell of FIG. 1, in accordance with some embodiments.

FIGS. 8A to 8D illustrate operation statuses of the memory cell of FIG. 1, in accordance with some embodiments.

FIGS. 9A to 9D illustrate operation statuses of the memory cell of FIG. 2, in accordance with some embodiments.

FIGS. 10A to 10D illustrate operation statuses of the memory cell of FIG. 2, in accordance with some embodiments.

FIG. 11 illustrates a circuit diagram of an example memory cell, in accordance with some embodiments.

FIG. 12 illustrates a circuit diagram of an example memory cell, in accordance with some embodiments.

FIGS. 13, 14, and 15 illustrate layouts to form the memory cell of FIG. 11 or FIG. 12, in accordance with some embodiments.

FIGS. 16A to 16D illustrate operation statuses of the memory cell of FIG. 11, in accordance with some embodiments.

FIGS. 17A to 17D illustrate operation statuses of the memory cell of FIG. 11, in accordance with some embodiments.

FIGS. 18A to 18D illustrate operation statuses of the memory cell of FIG. 12, in accordance with some embodiments.

FIGS. 19A to 19D illustrate operation statuses of the memory cell of FIG. 12, in accordance with some embodiments.

FIG. 20 illustrates a circuit diagram of an example memory cell, in accordance with some embodiments.

FIGS. 21A and 21B illustrate layouts to form the memory cell of FIG. 20, in accordance with some embodiments.

FIGS. 22A and 22B illustrate layouts to form the memory cell of FIG. 20, in accordance with some embodiments.

FIG. 23 illustrates a circuit diagram of an example memory cell, in accordance with some embodiments.

FIGS. 24A and 24B illustrate layouts to form the memory cell of FIG. 23, in accordance with some embodiments.

FIGS. 25A and 25B illustrate layouts to form the memory cell of FIG. 23, in accordance with some embodiments.

FIG. 26 illustrates a circuit diagram of an example memory cell, in accordance with some embodiments.

FIGS. 27A and 27B illustrate layouts to form the memory cell of FIG. 26, in accordance with some embodiments.

FIGS. 28A and 28B illustrate layouts to form the memory cell of FIG. 26, in accordance with some embodiments.

FIG. 29 is an example flow chart of a method for fabricating a memory device of FIG. 1 or FIG. 2, in accordance with some embodiments.

FIG. 30 is an example flow chart of a method for fabricating a memory device of FIG. 11 or FIG. 12, in accordance with some embodiments.

FIG. 31 is an example flow chart of a method for fabricating a memory device of FIG. 20, 23, or 26, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various forms of static and dynamic semiconductor storage cells have been adopted in modern integrated circuits. Static cells (e.g., a 6T-SRAM) continue to store data for as long as power is applied to them. In contrast, a dynamic storage cell (e.g., a 1T-DRAM, 3T-DRAM or 4T-DRAM) must be periodically refreshed or it loses the stored data. Static cells are generally faster, consume less power and have lower error rates, but have the disadvantage of requiring more space on a semiconductor chip. Generally, refreshing scheme on the dynamic storage cells only creates the pseudo static storage cells because the external access command is unpredictable and cannot be executed when the heavy external access occurs and interferes with the internal refresh operation. One way to solve the access/refresh conflict problem is to insert the refresh operation after the external access operation in the same clock cycle but it causes more cycle time or poorer performance.

Various circuitries use the dynamic storage cells but provide the static storage effect to reduce the space on the semiconductor chip. An SRAM is given a higher leakage current from the pre-charged bit line to the storage node via the pass transistor to retain the data. A 1T-DRAM is the smallest in area but the capacitor included in the memory cell is generally implemented as a three-dimensional configuration that increases the process numbers and the production cost. Moreover, because of the required destructive read and write-back, access time is increased when compared with a case in which the SRAM is employed. As such, these are not suitable for system-on-chip (SOC) applications since most of these SOC applications use the generic process provided by the majority of the foundries.

The present disclosure provides various embodiments of a dynamic random access memory cell, which is not required to have a capacitor with a three-dimensional configuration and can be fabricated in the same transistor processes as other transistors of the memory cell, and methods for operating and fabricating the same. For example, the dynamic random access memory cell, as disclosed herein, can include three operatively coupled transistors (sometimes referred to as a 3T-DRAM cell), which may be referred to as “write transistor,” “read transistor,” and “storage transistor,” respectively. In overview, the write transistor and read transistor are operatively coupled to a write bit line (WBL) and a read bit line (RBL), respectively, with the storage transistor providing a gate capacitance to retain data for the write operation and cell current for the read operation. Access speed of the disclosed memory cell can be similar to an SRAM cell since its read operation is non-destructive. Further, by constructing the memory cell in any of the following configurations, a total area of the memory cell can be significantly reduced, which allows to the disclosed memory cell to be integrated with high density.

In one aspect of the present disclosure, the WBL and RBL may be operatively combined with one single interconnect structure (e.g., one middle-end interconnect structure). As such, a read path and write path can share the same bit line (e.g., one back-end interconnect structure), which can reduce a cell height of the memory cell. Therefore, a total area of the disclosed memory cell can be significantly reduced. In another aspect of the present disclosure, the WBL and one terminal of the storage transistor can be operatively coupled to each other, which can also reduce the cell height of the memory cell. In yet another aspect of the present disclosure, the three transistors may be configured in a complementary field-effect-transistor (CFET) architecture, which allows a total area of the memory cell to be significantly reduced. For example, the storage transistor and read transistor may be formed in a first device layer/level, while the write transistor may be formed in a second device layer/level vertically disposed above or below the first one.

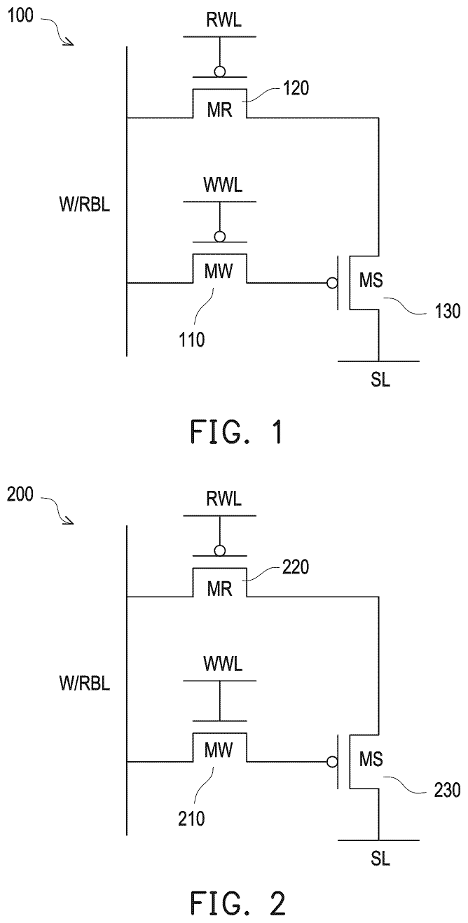

Referring to FIG. 1, an example circuit diagram of a memory cell 100 is depicted, in accordance with various embodiments of the present disclosure. In some embodiments, the memory cell 100 may be implemented as a dynamic random access memory cell, e.g., an embedded dynamic random access memory cell which is integrated on the same die or multi-chip module of an application-specific integrated circuit or microprocessor. For example, the memory cell 100 is configured in a three-transistor architecture, in which its read path and write path can be separated.

As shown, the memory cell 100 includes transistors 110, 120, and 130, which are herein referred to as “write transistor (MW) 110,” “read transistor (MR) 120,” and “storage transistor (MS) 130,” respectively. In some embodiments, each of the MW 110, MR 120, and MS 130 can be implemented as any of various of transistor architectures such as, for example, a planar transistor, a FinFET, a gate-all-around (GAA) transistor, or any suitable nanostructure transistor. Further, the MW 110, MR 120, and MS 130 may have the same conductive type, e.g., p-type, in the example of FIG. 1.

Specifically, the MW 110 has its gate connected to a write word line (WWL), the MR 120 has its gate connected to a read word line (RWL), and the MS 130 has its gate connected to a first one of the source or drain of the MW 110. The MW 110 has a second one of its source or drain connected to a combined write/read bit line (W/RBL); and the MR 120 has a first one of its source or drain connected to the W/RBL, and a second one of its source or drain connected to a first one of source or drain of the MS 130, with a second one of the MS 130's source or drain connected to a source line (SL). By combining the write bit line and read bit line that are typically isolated from each other in the existing dynamic random access memory cells (e.g., through a middle-end interconnect structure which will be shown below), at least one back-end interconnect structure can be avoided to form the memory cell 100. Consequently, a total area of the memory cell 100 can be advantageously reduced.

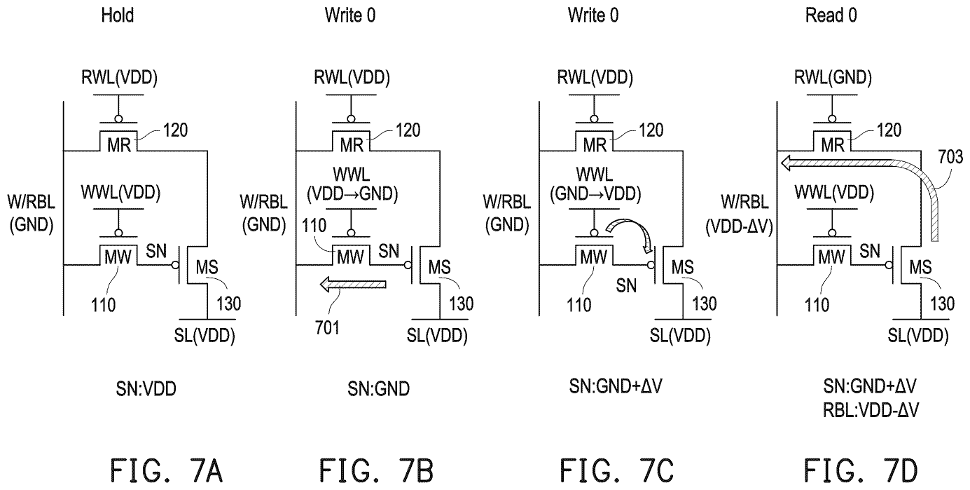

In brief overview, the MW 110 and MR 120 can be activated (e.g., turned on) through the WWL and RWL, respectively. The respective signals (e.g., voltages) applied on the WWL and RWL can be independently configured. As such, a write path/operation and a read path/operation of the memory cell 100 can be separated, with minimal interference. The MS 130 can provide its gate capacitance to retain data for the write operation and cell current for the read operation. Operations of the memory cell 100 will be discussed in further detail below with respect to FIGS. 7A-D and 8A-D.

FIG. 2 illustrates an example circuit diagram of another memory cell 200, in accordance with various embodiments of the present disclosure. In some embodiments, the memory cell 200 may be implemented as a dynamic random access memory cell, e.g., an embedded dynamic random access memory cell which is integrated on the same die or multi-chip module of an application-specific integrated circuit or microprocessor. For example, the memory cell 200 is configured in a three-transistor architecture, in which its read path and write path can be separated.

The memory cell 200 is substantially similar to the memory cell 100 except that a write transistor of the memory cell 200 has a different conductive type than other transistors of the memory cell 200. For example, the memory cell 200 includes transistors 210, 220, and 230, which are herein referred to as “write transistor (MW) 210,” “read transistor (MR) 220,” and “storage transistor (MS) 230,” respectively. In some embodiments, each of the MW 210, MR 220, and MS 230 can be implemented as any of various of transistor architectures such as, for example, a planar transistor, a FinFET, a gate-all-around (GAA) transistor, or any suitable nanostructure transistor. Further, the MW 210 may have a first conducive type, e.g., n-type, while the MR 220 and MS 230 may have a second, opposite conductive type, e.g., p-type, in the example of FIG. 2.

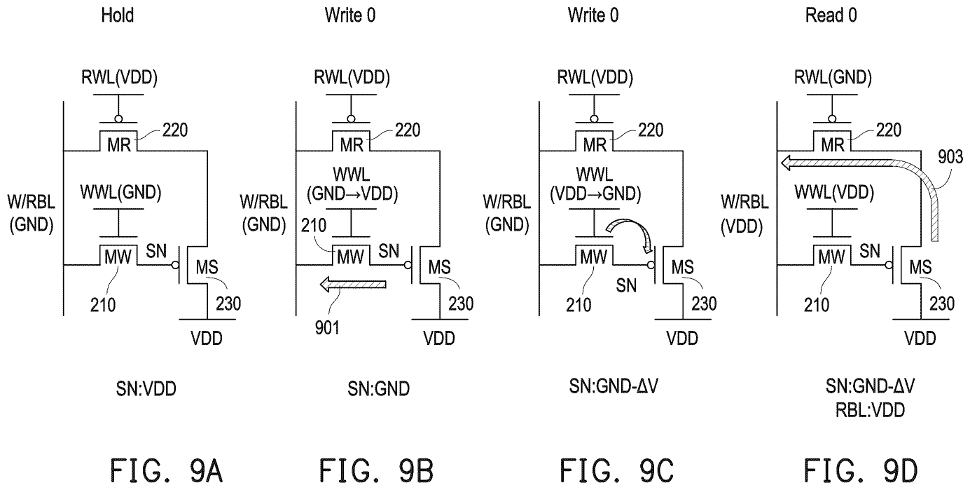

Specifically, the MW 210 has its gate connected to a write word line (WWL), the MR 220 has its gate connected to a read word line (RWL), and the MS 230 has its gate connected to a first one of the source or drain of the MW 210. The MW 210 has a second one of its source or drain connected to a combined write/read bit line (W/RBL); and the MR 220 has a first one of its source or drain connected to the W/RBL, and a second one of its source or drain connected to a first one of source or drain of the MS 230, with a second one of the MS 230's source or drain connected to a source line (SL). Similarly, operations of the memory cell 200 will be discussed in further detail below with respect to FIGS. 9A-D and 10A-D.

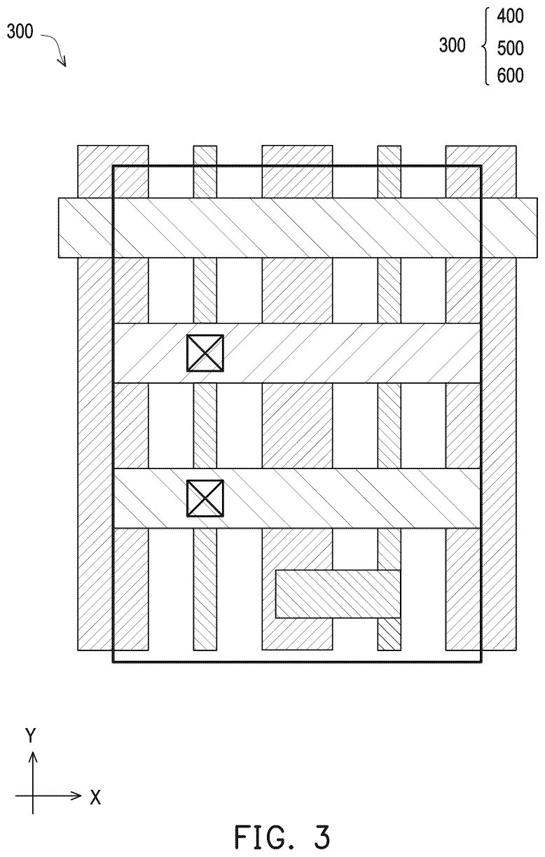

FIG. 3 illustrates an example layout design 300 of a memory cell configured in a three-transistor architecture, in accordance with various embodiments of the present disclosure. The layout 300 can be used to fabricate the memory cell 100 (or memory cell 200), in various embodiments. Accordingly, some of the reference numerals, used above in FIGS. 1-2, may be reused in the discussion of FIG. 3. Although the layout 300 shown in FIG. 3 is used to fabricate each of the transistors of the memory cell 100/200 as a FinFET, it should be understood that the layout 300 may be used to fabricate the memory cell 100/200 with any of various other types of transistors such as, for example, nanowire transistors, nanosheet transistors, etc., while remaining within the scope of the present disclosure.

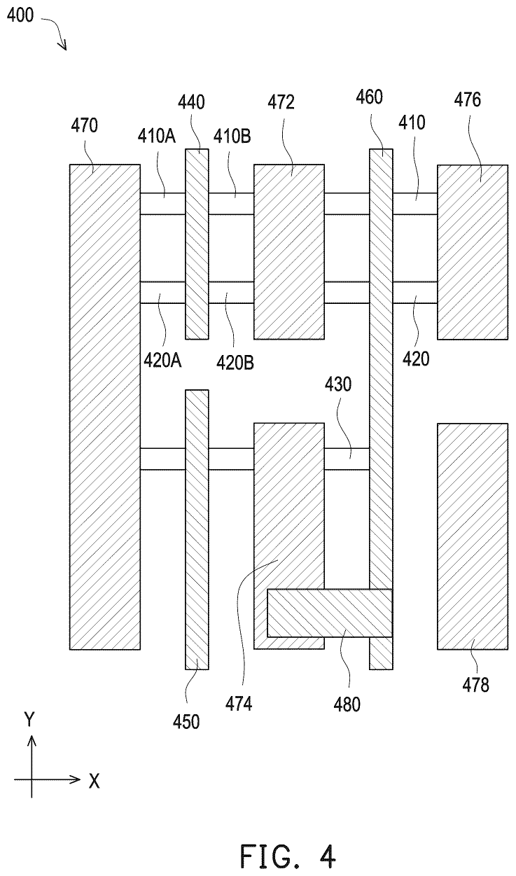

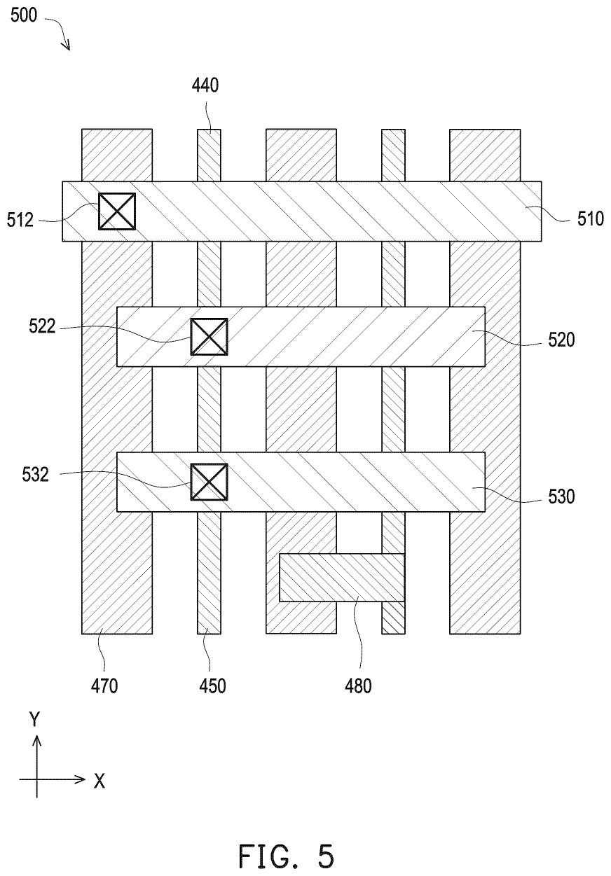

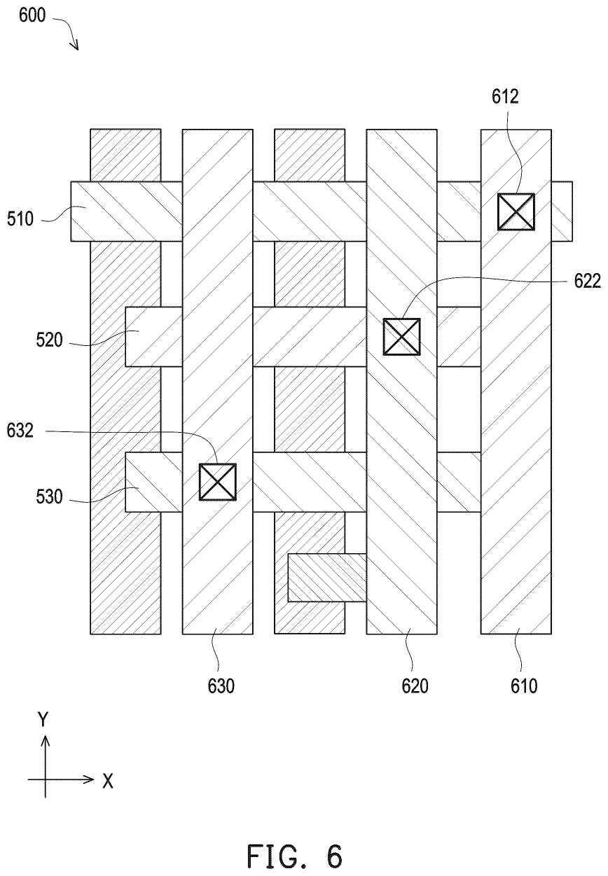

The layout 300 of FIG. 3 includes a plural number of patterns disposed across multiple device layers/levels vertically disposed on top of one another. Alternatively stated, some of the patterns shown in FIG. 3 may be overlapped with one another. In the following discussion, solely for the purposes of clarity, the patterns of the layout 300 of FIG. 3 are separated into three different levels that are illustrated in FIGS. 4, 5, and 6, respectively. For example, the layout 300 includes level (layout) 400 having a number of patterns configured to form active regions, gate structures, and middle-end interconnect structures (FIG. 4); level (layout) 500 having a number of patterns configured to form first level back-end interconnect structures (FIG. 5); and level (layout) 600 having a number of patterns configured to form second level back-end interconnect structures (FIG. 6).

Referring first to FIG. 4, the layout 400 includes patterns 410, 420, and 430 extending along the X direction. The patterns 410 to 430 are each configured to form an active region (e.g., a fin structure, a well, a protruding structure having alternately stacked silicon and silicon germanium layers, etc., which is sometimes referred to as an oxide diffusion (OD) region) over a substrate. The layout 400 includes patterns 440, 450, and 460 extending along the Y direction. The patterns 440 to 460 are each configured to form a gate structure (e.g., a polysilicon gate, a metal gate, etc.) over the active regions. Accordingly, the patterns 410 to 430 may each be referred to as an active region, and the patterns 440 to 460 may each be referred to as a gate structure. In some embodiments, the active regions 410 and 420, in parallel with each other, may extend farther than the active region 430. As such, the gate structure 460 may overlay an end of the active region 430, while traversing across a non-end portion of any of the active region 410 or 420.

In some embodiments, each of the gate structures can overlay at least one active region to form a transistor. For example in FIG. 4, the gate structure 440, together with the active regions 410 and 420, can form the MR 120/220 (FIG. 1/2); the gate structure 460, together with the active regions 410 and 420, can form the MS 130/230; and the gate structure 450, together with the active region 430, can from the MW 110/210. Specifically, the gate structures 440, 450, and 460 can operatively serve as gates of the MR 120/220, MW 110/210, and MS 130/230, respectively. Further, the portions of each active region on opposite sides of the overlaying gate structure (i.e., the portions not overlaid by the gate structure) can form the corresponding transistor's source and drain, respectively. As a representative example, portions of the active regions 410 and 420 on the left-hand side of the gate structure 440, 410A and 420A, can collectively form one of the source or drain of the MR 120/220; and portions of the active regions 410 and 420 on the right-hand side of the gate structure 440, 410B and 420B, can collectively form the other of the source or drain of the MR 120/220. When using the layout 300 to form the memory cell 100, the active regions 410 to 430 may have the same conductivity (e.g., p-type); and when using the layout 300 to form the memory cell 200, the active regions 410 to 420 may have a first conductivity (e.g., p-type), while the active region 430 may have a second conductivity (e.g., n-type).

The layout 400 further includes patterns 470, 472, 474, 476, and 478 extending along the Y direction and disposed between adjacent gate structures (i.e., overlaying the source or drain of a transistor). The patterns 470 to 478 are each configured to form a middle-end interconnect structure (sometimes referred to as “MD”). Accordingly, the patterns 470 to 478 may each be referred to as an MD. Such an MD is generally configured to electrically connect the source or drain of a transistor to the source or drain of another transistor or to a supply voltage. For example, the MD 470 can connect one source/drain of the MR 120/220 to one source/drain of the MW 110/210. As such, the MD 470 can electrically couple one source/drain of the MR 120/220 to one source/drain of the MW 110/210, as depicted in the circuit diagram of FIGS. 1-2. In some embodiments, the MD 470 may operatively serve as at least a portion of the W/RBL (sometimes referred to as W/RBL 470). In another example, the MD 476 can connect one source/drain of the MS to the SL (FIG. 1/2) that is tied to a supply voltage (e.g., VDD). The layout 400 further includes a pattern 480 extending along the X direction to connect the MD 474 to the gate structure 460. As such, the MD 474 can electrically couple the other source/drain of the MW 110/210 to the gate of the MS 130/230, as depicted in the circuit diagram of FIGS. 1-2.

Referring next to FIG. 5, the layout 500 includes patterns 510, 520, and 530 extending along the X direction. The patterns 510 to 530 are each configured to form an interconnect structure disposed in a bottommost one of metallization layers (e.g., M0 layer) disposed over the substrate. Accordingly, the patterns 510 to 530 may each be referred to as an M0 interconnect structure. In some embodiments, the M0 interconnect structures 510 to 530 can be in electrical connection with a corresponding component formed in the layer 400. For example, the M0 interconnect structure 510 is in electrical connection with the MD 470 (operatively serving as the W/RBL in FIG. 1/2) through a via structure 512; the M0 interconnect structure 520 is in electrical connection with the gate structure 440 (operatively serving as the gate of the MR 120/220 in FIG. 1/2) through a via structure 522; and the M0 interconnect structure 530 is in electrical connection with the gate structure 450 (operatively serving as the gate of the MW 110/210 in FIG. 1/2) through a via structure 532. As such, the M0 interconnect structures 510, 520, and 530 are sometimes referred to as W/RBL jumper 510, RWL jumper 520, and WWL jumper 530, respectively.

Referring then to FIG. 6, the layout 600 includes patterns 610, 620, and 630 extending along the Y direction. The patterns 610 to 630 are each configured to form an interconnect structure disposed in a next bottommost one of the metallization layers (e.g., M1 layer) disposed over the substrate. Accordingly, the patterns 610 to 630 may each be referred to as an M1 interconnect structure. In some embodiments, the M1 interconnect structures 610 to 630 can be in electrical connection with a corresponding component formed in the layer 500. For example, the M1 interconnect structure 610 is in electrical connection with the M0 interconnect structure 510 (W/RBL jumper) through a via structure 612; the M1 interconnect structure 620 is in electrical connection with the M0 interconnect structure 520 (RWL jumper) through a via structure 622; and the M1 interconnect structure 630 is in electrical connection with the M0 interconnect structure 530 (WWL jumper) through a via structure 632. As such, the M1 interconnect structures 620 and 630 are sometimes referred to as RWL 620 and WWL 630, respectively.

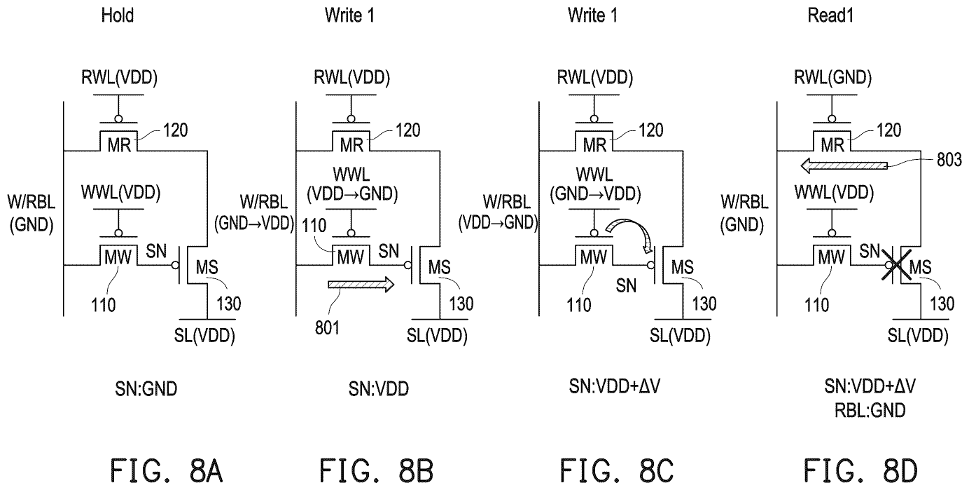

FIGS. 7A to 7D and 8A to 8D illustrate various example operation statuses of the memory cell 100 (FIG. 1), in accordance with various embodiments. For example, FIGS. 7A to 7D illustrate the operation statuses of the memory cell 100, when writing and reading a first logic state into and from the memory cell 100; and FIGS. 8A to 8D illustrate the operation statuses of the memory cell 100, when writing and reading a second logic state into and from the memory cell 100. It should be understood that the voltages shown in in FIGS. 7A to 8D are merely illustrative examples, and should not be limited thereto.

Referring first to FIG. 7A, the memory cell 100 is in a “hold” state, e.g., after the memory cell 100 is written with a logic 1. As shown, the RWL and WWL are applied with a first supply voltage corresponding to a high logic state (e.g., VDD), thus turning off the MR and MW, respectively. With both the MR and MW being turned off (both write and read paths are cut off), the memory cell 100, in such a hold state, may hold data written to a gate (capacitance) of the MS (e.g., a logic 1 or VDD). Such a node (the gate of the MS) is sometimes referred to as “SN.” In some embodiments, the SL and W/RBL are applied with the first supply voltage (VDD) and a second supply voltage corresponding to a low logic state (e.g., ground or GND), respectively.

Referring next to FIGS. 7B and 7C, the memory cell 100 is in a “write 0” state, e.g., writing a logic 0 to the memory cell 100. As shown in FIG. 7B, the voltage applied to the WWL may transition from VDD to GND (with the W/RBL, RWL, and SL being applied with GND, VDD, and VDD, respectively). The MW is thus turned on, conducting a write path 701 from the gate of the MS to the W/RBL. As such, data of a logic 0 can be written to the gate (capacitance) of the MS, causing a voltage of SN to be equal to about GND. Next in FIG. 7C, the voltage applied to the WWL may transition from GND to VDD (with the W/RBL, RWL, and SL being applied with GND, VDD, and VDD, respectively), which turns off the MW. Accordingly, the voltage of SN may be pulled up a bit from GND, e.g., GND+ΔV. ΔV may be a voltage drop induced across the gate of MW and the source/drain of MW.

Referring then to FIG. 7D, the memory cell 100 is in a “read 0” state, e.g., after being written with a logic 0. As shown, the voltage applied to the gate of the MW (WWL) may remain at VDD, while a voltage applied to the gate of the MR (RWL) may transition from VDD to GND. Accordingly, the MR is turned on, conducting a read path 703 from one of the source/drain of the MS (VDD), through the MR, and to the W/RBL. In some embodiments, with the voltage of SN remaining at GND+ΔV, a voltage present on the W/RBL may become VDD−ΔV. The W/RBL can be operatively connected to a sense amplifier to detect such a voltage level so as to determine that the data stored in the memory cell 100 is a logic 0.

Different from the operations of FIGS. 7A-D where a logic 0 is written to and read from the memory cell 100, FIGS. 8A-D illustrate operations statuses of the memory cell 100 when a logic 1 is written to and read from the memory cell 100.

Referring first to FIG. 8A, the memory cell 100 is in a “hold” state, e.g., after the memory cell 100 is written with a logic 0. As shown, the RWL and WWL are applied with a first supply voltage corresponding to a high logic state (e.g., VDD), thus turning off the MR and MW, respectively. With both the MR and MW being turned off (both write and read paths are cut off), the memory cell 100, in such a hold state, may hold data written to a gate (capacitance) of the MS (e.g., a logic 0 or GND). In some embodiments, the SL and W/RBL are applied with the first supply voltage (VDD) and a second supply voltage corresponding to a low logic state (e.g., GND), respectively.

Referring next to FIGS. 8B and 8C, the memory cell 100 is in a “write 1” state, e.g., writing a logic 1 to the memory cell 100. As shown in FIG. 8B, the voltage applied to the WWL may transition from VDD to GND and the voltage applied to the W/RBL may transition from GND to VDD (with the RWL and SL being both applied with VDD). The MW is thus turned on, conducting a write path 801 from the W/RBL to the gate of the MS. As such, data of a logic 1 can be written to the gate (capacitance) of the MS, causing a voltage of SN to be equal to about VDD. Next in FIG. 8C, the voltage applied to the WWL may transition from GND to VDD and the voltage applied to the W/RBL may transition from VDD to GND (with the RWL and SL being both applied with VDD), which turns off the MW. Accordingly, the voltage of SN may be pulled up a bit from VDD, e.g., VDD+ΔV. ΔV may be a voltage drop induced across the gate of MW and the source/drain of MW.

Referring then to FIG. 8D, the memory cell 100 is in a “read 1” state, e.g., after being written with a logic 1. As shown, the voltage applied to the gate of the MW (WWL) may remain at VDD, while a voltage applied to the gate of the MR (RWL) may transition from VDD to GND. Accordingly, the MR is turned on, conducting a read path 803 through the MR and to the W/RBL. Since the MS is turned off (with the voltage of SN present at VDD), the voltage present on the W/RBL may remain at GND. The W/RBL can be operatively connected to a sense amplifier to detect such a voltage level so as to determine that the data stored in the memory cell 100 is a logic 0.

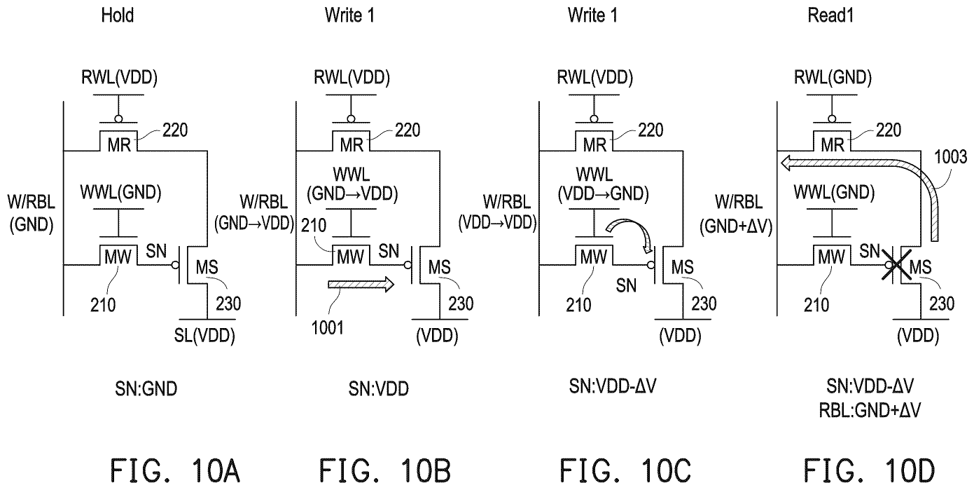

FIGS. 9A to 9D and 10A to 10D illustrate various example operation statuses of the memory cell 200 (FIG. 2), in accordance with various embodiments. For example, FIGS. 9A to 9D illustrate the operation statuses of the memory cell 200, when writing and reading a first logic state into and from the memory cell 200; and FIGS. 10A to 10D illustrate the operation statuses of the memory cell 200, when writing and reading a second logic state into and from the memory cell 200. It should be understood that the voltages shown in in FIGS. 9A to 10D are merely illustrative examples, and should not be limited thereto.

Referring first to FIG. 9A, the memory cell 200 is in a “hold” state, e.g., after the memory cell 100 is written with a logic 1. As shown, the RWL and WWL are applied with a first supply voltage corresponding to a high logic state (e.g., VDD) and a second supply voltage corresponding to a low logic state (e.g., GND), thus turning off the MR and MW, respectively. With both the MR and MW being turned off (both write and read paths are cut off), the memory cell 200, in such a hold state, may hold data written to a gate (capacitance) of the MS (e.g., a logic 1 or VDD). Such a node (the gate of the MS) is sometimes referred to as “SN.” In some embodiments, the SL and W/RBL are applied with the first supply voltage (VDD) and the second supply voltage (GND), respectively.

Referring next to FIGS. 9B and 9C, the memory cell 200 is in a “write 0” state, e.g., writing a logic 0 to the memory cell 200. As shown in FIG. 9B, the voltage applied to the WWL may transition from GND to VDD (with the W/RBL, RWL, and SL being applied with GND, VDD, and VDD, respectively). The MW is thus turned on, conducting a write path 901 from the gate of the MS to the W/RBL. As such, data of a logic 0 can be written to the gate (capacitance) of the MS, causing a voltage of SN to be equal to about GND. Next in FIG. 9C, the voltage applied to the WWL may transition from VDD to GND (with the W/RBL, RWL, and SL being applied with GND, VDD, and VDD, respectively), which turns off the MW. Accordingly, the voltage of SN may be pulled down a bit from GND, e.g., GND−ΔV. ΔV may be a voltage drop induced across the gate of MW and the source/drain of MW.

Referring then to FIG. 9D, the memory cell 200 is in a “read 0” state, e.g., after being written with a logic 0. As shown, the voltage applied to the gate of the MW (WWL) may remain at VDD, while a voltage applied to the gate of the MR (RWL) may transition from VDD to GND. Accordingly, the MR is turned on, conducting a read path 903 from one of the source/drain of the MS (VDD), through the MR, and to the W/RBL. In some embodiments, with the voltage of SN remaining at GND−ΔV, a voltage present on the W/RBL may become VDD−ΔV. The W/RBL can be operatively connected to a sense amplifier to detect such a voltage level so as to determine that the data stored in the memory cell 200 is a logic 0.

Different from the operations of FIGS. 9A-D where a logic 0 is written to and read from the memory cell 200, FIGS. 10A-D illustrate operations statuses of the memory cell 200 when a logic 1 is written to and read from the memory cell 200.

Referring first to FIG. 10A, the memory cell 200 is in a “hold” state, e.g., after the memory cell 200 is written with a logic 1. As shown, the RWL and WWL are applied with a first supply voltage corresponding to a high logic state (e.g., VDD) and a second supply voltage corresponding to a low logic state (e.g., GND), thus turning off the MR and MW, respectively. With both the MR and MW being turned off (both write and read paths are cut off), the memory cell 200, in such a hold state, may hold data written to a gate (capacitance) of the MS (e.g., a logic 0 or GND). In some embodiments, the SL and W/RBL are applied with the first supply voltage (VDD) and the second supply voltage (GND), respectively.

Referring next to FIGS. 10B and 10C, the memory cell 200 is in a “write 1” state, e.g., writing a logic 1 to the memory cell 200. As shown in FIG. 10B, the voltage applied to the WWL may transition from GND to VDD and the voltage applied to the W/RBL may transition from GND to VDD (with the RWL and SL being both applied with VDD). The MW is thus turned on, conducting a write path 1001 from the W/RBL to the gate of the MS. As such, data of a logic 1 can be written to the gate (capacitance) of the MS, causing a voltage of SN to be equal to about VDD. Next in FIG. 10C, the voltage applied to the WWL may transition from VDD to GND and the voltage applied to the W/RBL may transition from VDD to GND (with the RWL and SL being both applied with VDD), which turns off the MW. Accordingly, the voltage of SN may be pulled down a bit from VDD, e.g., VDD−ΔV. ΔV may be a voltage drop induced across the gate of MW and the source/drain of MW.

Referring then to FIG. 10D, the memory cell 200 is in a “read 1” state, e.g., after being written with a logic 1. As shown, the voltage applied to the gate of the MW (WWL) may remain at GND, while a voltage applied to the gate of the MR (RWL) may transition from VDD to GND. Accordingly, the MR is turned on, conducting a read path 1003 through the MR and to the W/RBL. Since the MS is turned off (with the voltage of SN present at VDD−ΔV), the voltage present on the W/RBL may become about GND+ΔV. The W/RBL can be operatively connected to a sense amplifier to detect such a voltage level so as to determine that the data stored in the memory cell 200 is a logic 0.

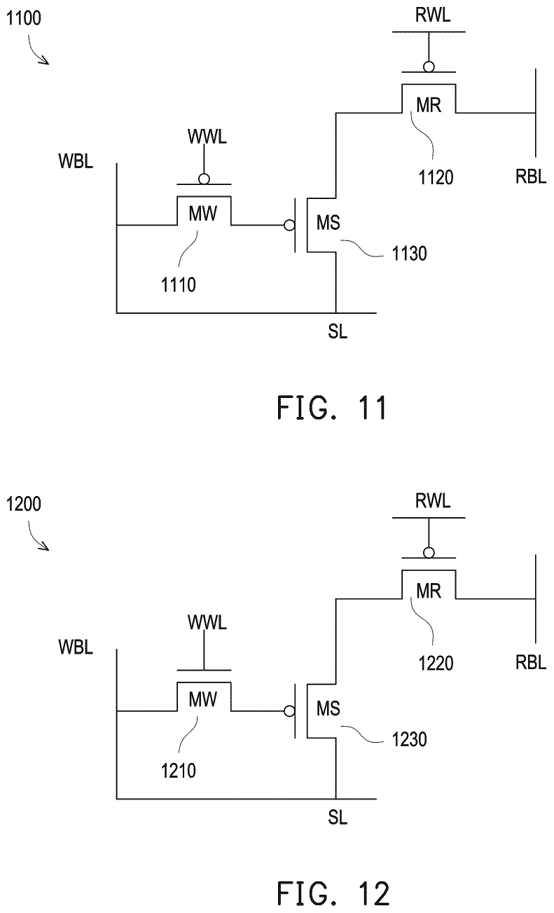

Referring to FIG. 11, an example circuit diagram of a memory cell 1100 is depicted, in accordance with various embodiments of the present disclosure. In some embodiments, the memory cell 1100 may be implemented as a dynamic random access memory cell, e.g., an embedded dynamic random access memory cell which is integrated on the same die or multi-chip module of an application-specific integrated circuit or microprocessor. For example, the memory cell 1100 is configured in a three-transistor architecture, in which its read path and write path can be separated.

As shown, the memory cell 1100 includes transistors 1110, 1120, and 1130, which are herein referred to as “write transistor (MW) 1110,” “read transistor (MR) 1120,” and “storage transistor (MS) 1130,” respectively. In some embodiments, each of the MW 1110, MR 1120, and MS 1130 can be implemented as any of various of transistor architectures such as, for example, a planar transistor, a FinFET, a gate-all-around (GAA) transistor, or any suitable nanostructure transistor. Further, the MW 1110, MR 1120, and MS 1130 may have the same conductive type, e.g., p-type, in the example of FIG. 11.

Specifically, the MW 1110 has its gate connected to a write word line (WWL), the MR 1120 has its gate connected to a read word line (RWL), and the MS 1130 has its gate connected to a first one of the source or drain of the MW 1110. The MW 1110 has a second one of its source or drain connected to a write bit line (WBL); and the MR 1120 has a first one of its source or drain connected to the RBL, and a second one of its source or drain connected to a first one of source or drain of the MS 1130, with a second one of the MS 1130's source or drain operatively connected to the WBL (e.g., no separated source line (SL)). By incorporating the SL into the WBL (e.g., through a back-end interconnect structure which will be shown below), a total area of the memory cell 1100 can be advantageously reduced.

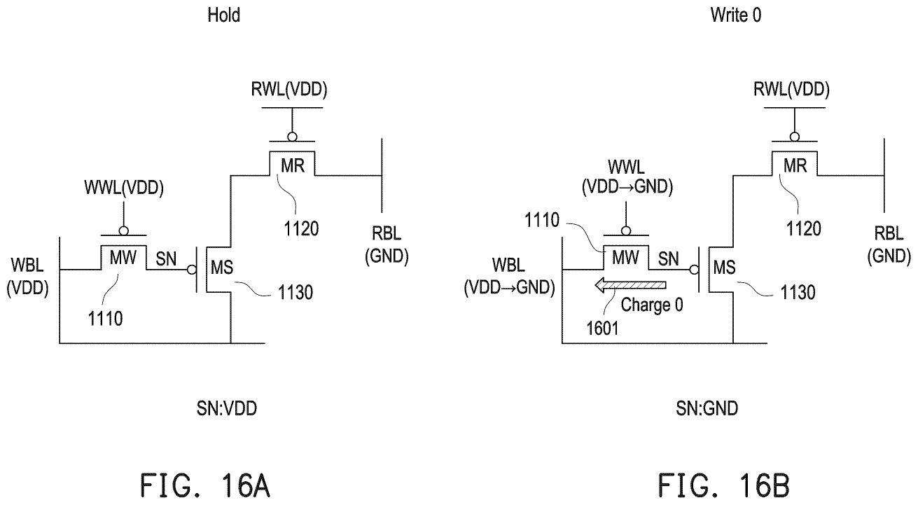

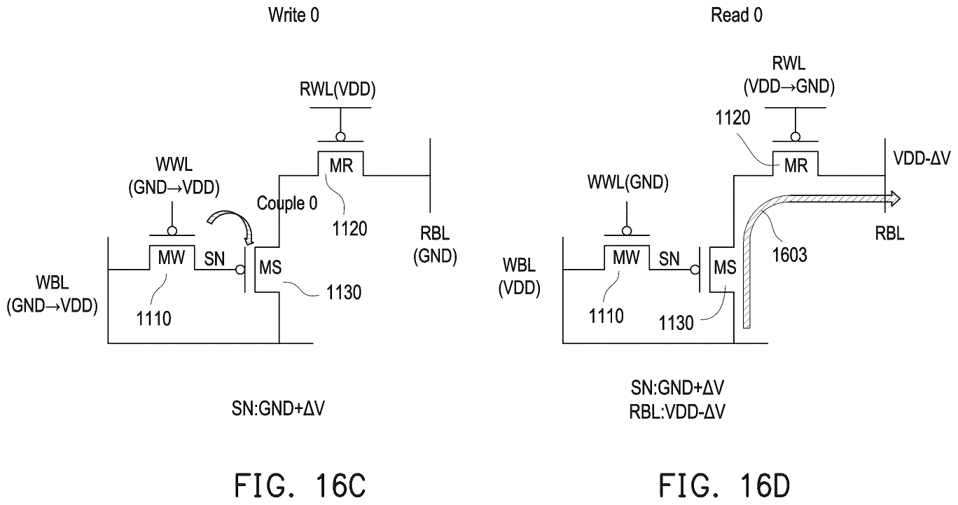

In brief overview, the MW 1110 and MR 1120 can be activated (e.g., turned on) through the WWL and RWL, respectively. The respective signals (e.g., voltages) applied on the WWL and RWL can be independently configured. As such, a write path/operation and a read path/operation of the memory cell 1100 can be separated, with minimal interference. The MS 1130 can provide its gate capacitance to retain data for the write operation and cell current for the read operation. Operations of the memory cell 1100 will be discussed in further detail below with respect to FIGS. 16A-D and 17A-D.

FIG. 12 illustrates an example circuit diagram of another memory cell 1200, in accordance with various embodiments of the present disclosure. In some embodiments, the memory cell 1200 may be implemented as a dynamic random access memory cell, e.g., an embedded dynamic random access memory cell which is integrated on the same die or multi-chip module of an application-specific integrated circuit or microprocessor. For example, the memory cell 1200 is configured in a three-transistor architecture, in which its read path and write path can be separated.

The memory cell 1200 is substantially similar to the memory cell 1100 except that a write transistor of the memory cell 1200 has a different conductive type than other transistors of the memory cell 1200. For example, the memory cell 1200 includes transistors 1210, 1220, and 1230, which are herein referred to as “write transistor (MW) 1210,” “read transistor (MR) 1220,” and “storage transistor (MS) 1230,” respectively. In some embodiments, each of the MW 1210, MR 1220, and MS 1230 can be implemented as any of various of transistor architectures such as, for example, a planar transistor, a FinFET, a gate-all-around (GAA) transistor, or any suitable nanostructure transistor. Further, the MW 1210 may have a first conducive type, e.g., n-type, while the MR 1220 and MS 1230 may have a second, opposite conductive type, e.g., p-type, in the example of FIG. 12.

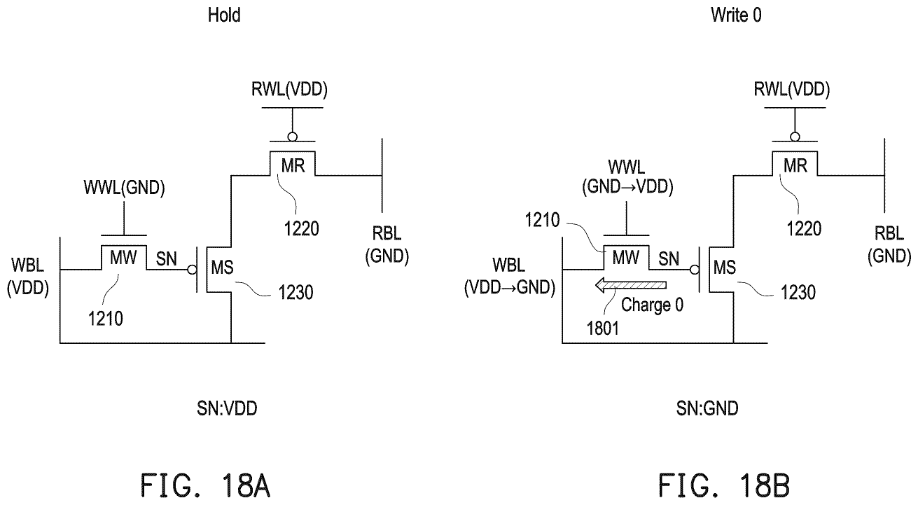

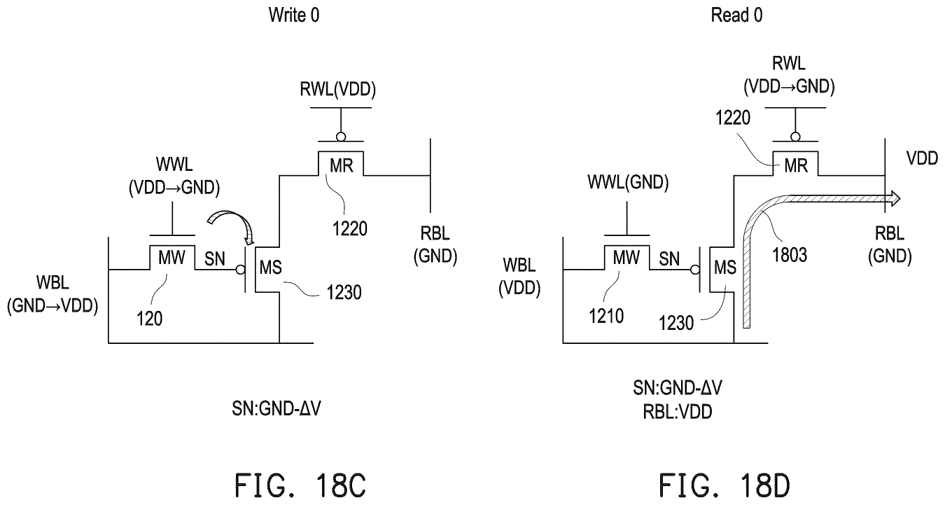

Specifically, the MW 1210 has its gate connected to a write word line (WWL), the MR 1220 has its gate connected to a read word line (RWL), and the MS 1230 has its gate connected to a first one of the source or drain of the MW 1210. The MW 1210 has a second one of its source or drain connected to a write bit line (WBL); and the MR 1220 has a first one of its source or drain connected to a read bit line (RBL), and a second one of its source or drain connected to a first one of source or drain of the MS 1230, with a second one of the MS 1230's source or drain operatively connected to the WBL (e.g., no separated source line (SL)). Similarly, operations of the memory cell 1200 will be discussed in further detail below with respect to FIGS. 18A-D and 19A-D.

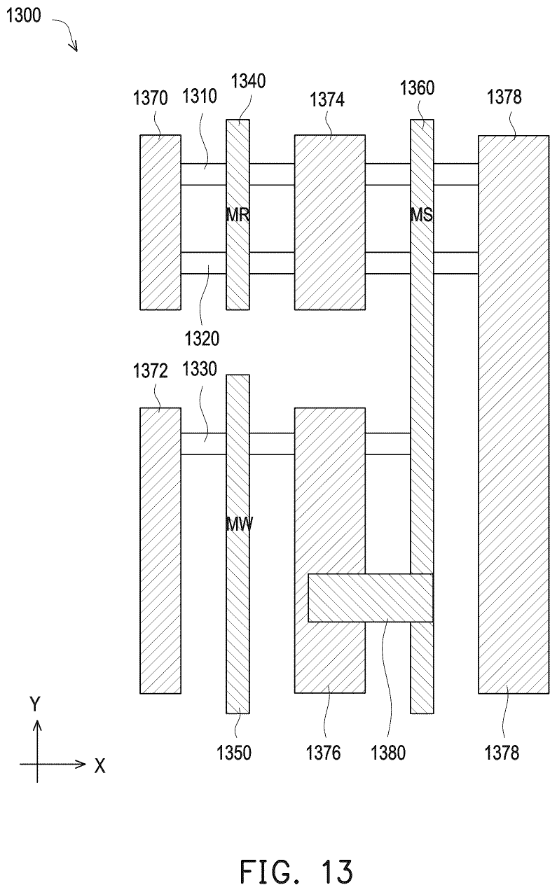

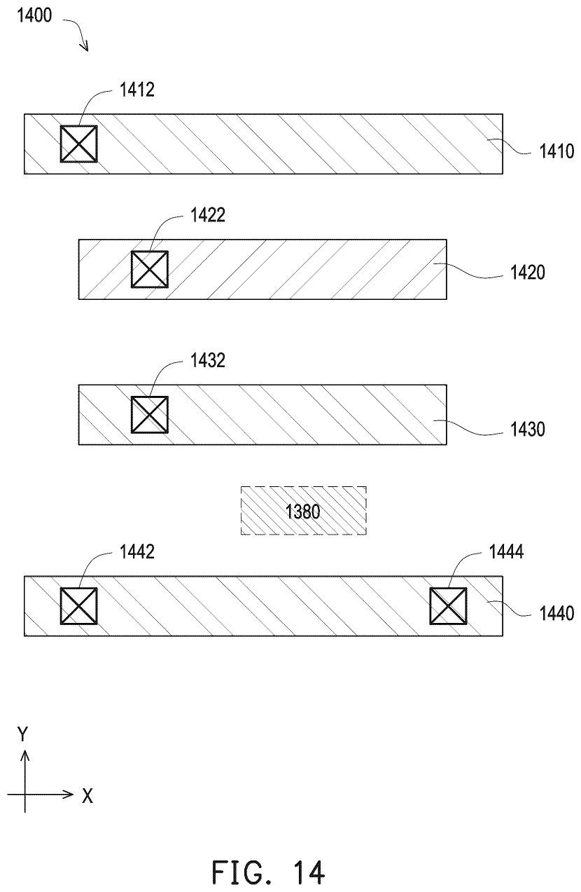

FIGS. 13, 14, and 15 respectively illustrate example layout designs of a memory cell, 1300, 1400, and 1500, configured in a three-transistor architecture which are disposed in different device layers/levels, in accordance with various embodiments of the present disclosure. The layouts 1300 to 1500, collectively, can be used to fabricate the memory cell 1100 (or memory cell 1200), in various embodiments. Accordingly, some of the reference numerals, used above in FIGS. 11-12, may be reused in the discussion of FIGS. 13-15. Although the layouts 1300-1500 shown in FIGS. 13-15 are used to fabricate each of the transistors of the memory cell 1100/1200 as a FinFET, it should be understood that the layouts 1300-1500 may be used to fabricate the memory cell 1100/1200 with any of various other types of transistors such as, for example, nanowire transistors, nanosheet transistors, etc., while remaining within the scope of the present disclosure.

Referring first to FIG. 13, the layout 1300 includes patterns 1310, 1320, and 1330 extending along the X direction. The patterns 1310 to 1330 are each configured to form an active region (e.g., a fin structure, a well, a protruding structure having alternately stacked silicon and silicon germanium layers, etc., which is sometimes referred to as an oxide diffusion (OD) region) over a substrate. The level 1300 includes patterns 1340, 1350, and 1360 extending along the Y direction. The patterns 1340 to 1360 are each configured to form a gate structure (e.g., a polysilicon gate, a metal gate, etc.) over the active regions. Accordingly, the patterns 1310 to 1330 may each be referred to as an active region, and the patterns 1340 to 1360 may each be referred to as a gate structure. In some embodiments, the active regions 1310 and 1320, in parallel with each other, may extend farther than the active region 1330. As such, the gate structure 1360 may overlay an end of the active region 1330, while traversing across a non-end portion of any of the active region 1310 or 1320.

In some embodiments, each of the gate structures can overlay at least one active region to form a transistor. For example in FIG. 13, the gate structure 1340, together with the active regions 1310 and 1320, can form the MR 1120/1220 (FIG. 11/12); the gate structure 1360, together with the active regions 1310 and 1320, can form the MS 1130/1230; and the gate structure 1350, together with the active region 1330, can from the MW 1110/1210. Specifically, the gate structures 1340, 1350, and 1360 can operatively serve as gates of the MR 1120/1220, MW 1110/1210, and MS 1130/1230, respectively. Further, the portions of each active region on opposite sides of the overlaying gate structure (i.e., the portions not overlaid by the gate structure) can form the corresponding transistor's source and drain, respectively. As a representative example, portions of the active regions 1310 and 1320 on the left-hand side of the gate structure 1340 can collectively form one of the source or drain of the MR 1120/1220; and portions of the active regions 1310 and 1320 on the right-hand side of the gate structure 1340 can collectively form the other of the source or drain of the MR 1120/1220. When using the layout 1300 to form the memory cell 1100, the active regions 1310 to 1330 may have the same conductivity (e.g., p-type); and when using the layout 1300 to form the memory cell 1200, the active regions 1310 to 1320 may have a first conductivity (e.g., p-type), while the active region 1330 may have a second conductivity (e.g., n-type).

The layout 1300 further includes patterns 1370, 1372, 1374, 1376, and 1378 extending along the Y direction and disposed between adjacent gate structures (i.e., overlaying the source or drain of a transistor). The patterns 1370 to 1378 are each configured to form a middle-end interconnect structure (sometimes referred to as “MD”). Accordingly, the patterns 1370 to 1378 may each be referred to as an MD. Such an MD is generally configured to electrically connect the source or drain of a transistor to the source or drain of another transistor or to a supply voltage. For example, the MD 1370 can connect one source/drain of the MR 1120/1220 to a RBL, as depicted in the circuit diagram of FIGS. 11-12. In another example, the MD 1370 can connect one source/drain of the MW 1110/1210 to a WBL, which may be coupled to a SL that is connected to one source/drain of the MS 1130/1230 through a back-end interconnect structure, as depicted in the circuit diagram of FIGS. 11-12. The layout 1300 further includes a pattern 1380 extending along the X direction to connect the MD 1376 to the gate structure 1360. As such, the MD 1376 can electrically couple the other source/drain of the MW 1110/1210 to the gate of the MS 1130/1230, as depicted in the circuit diagram of FIGS. 11-12.

Referring next to FIG. 14, the layout 1400 includes patterns 1410, 1420, 1430, and 1440 extending along the X direction. The patterns 1410 to 1440 are each configured to form an interconnect structure disposed in a bottommost one of metallization layers (e.g., M0 layer) disposed over the substrate. Accordingly, the patterns 1410 to 1440 may each be referred to as an M0 interconnect structure. In some embodiments, the M0 interconnect structures 1410 to 1440 can be in electrical connection with a corresponding component formed in the layout 1300. For example, the M0 interconnect structure 1410 is in electrical connection with the MD 1370 (operatively serving as the RBL in FIG. 11/12) through a via structure 1412; the M0 interconnect structure 1420 is in electrical connection with the gate structure 1340 (operatively serving as the gate of the MR 1120/1220 in FIG. 11/12) through a via structure 1422; the M0 interconnect structure 1430 is in electrical connection with the gate structure 1350 (operatively serving as the gate of the MW 1110/1210 in FIG. 11/12) through a via structure 1432; and the M0 interconnect structure 1440 is in electrical connection with the MD 1372 (operatively serving as the WBL in FIG. 11/12) and MD 1378 (operatively serving as the SL in FIG. 11/12) through via structures 1442 and 1444, respectively. As such, the M0 interconnect structures 1410, 1420, 1430, and 1440 are sometimes referred to as RBL jumper 1410, RWL jumper 1420, WWL jumper 1430, and WBL jumper 1440, respectively. It should be noted that the WBL (one source/drain of the MW 1110/1210) and SL (one source/drain of the MS 1130/1230) are connected to each other, as depicted in FIG. 11/12, through the WBL jumper 1440.

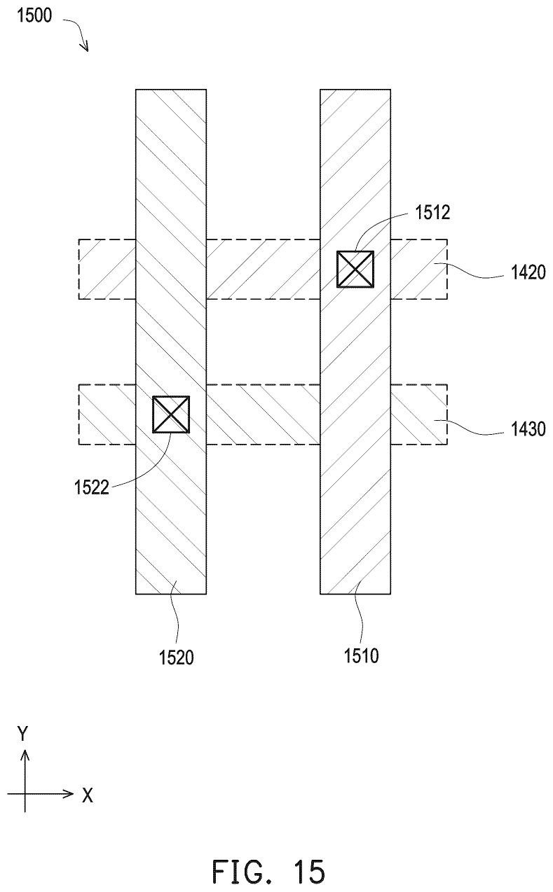

Referring then to FIG. 15, the layout 1500 includes patterns 1510 and 1520 extending along the Y direction. The patterns 1510 to 1520 are each configured to form an interconnect structure disposed in a next bottommost one of the metallization layers (e.g., M1 layer) disposed over the substrate. Accordingly, the patterns 1510 to 1520 may each be referred to as an M1 interconnect structure. In some embodiments, the M1 interconnect structures 1510 to 1520 can be in electrical connection with a corresponding component formed in the layout 1400. For example, the M1 interconnect structure 1510 is in electrical connection with the M0 interconnect structure 1420 (RWL jumper) through a via structure 1512; and the M1 interconnect structure 1520 is in electrical connection with the M0 interconnect structure 1430 (WWL jumper) through a via structure 1522. As such, the M1 interconnect structures 1510 and 1520 are sometimes referred to as RWL 1510 and WWL 1520, respectively.

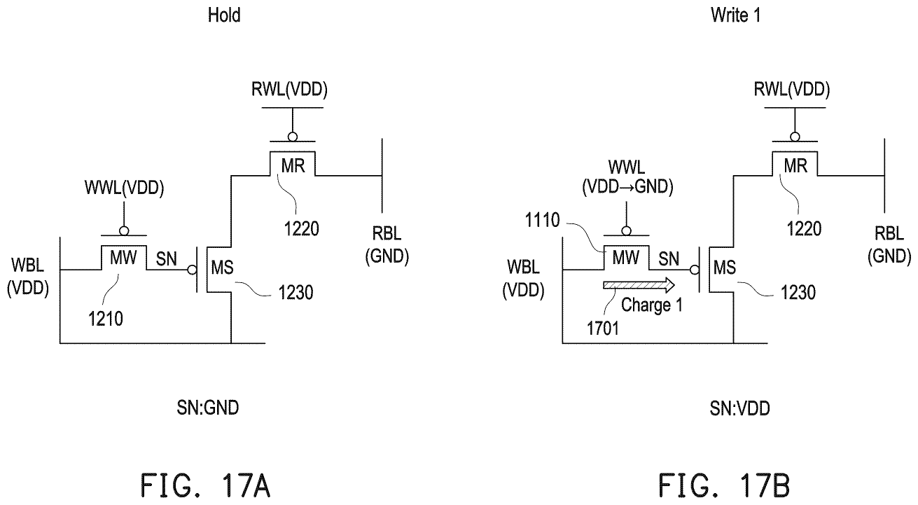

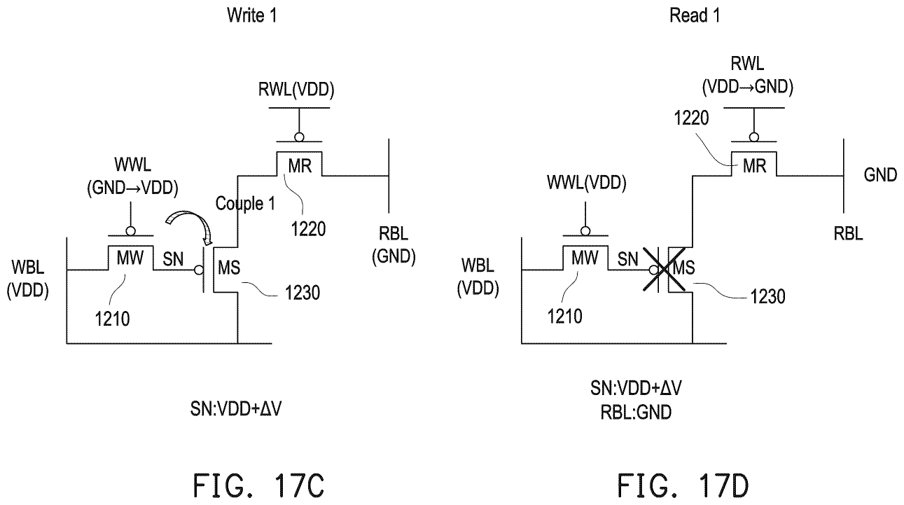

FIGS. 16A to 16D and 17A to 17D illustrate various example operation statuses of the memory cell 1100 (FIG. 11), in accordance with various embodiments. For example, FIGS. 16A to 16D illustrate the operation statuses of the memory cell 1100, when writing and reading a first logic state into and from the memory cell 1100; and FIGS. 17A to 17D illustrate the operation statuses of the memory cell 1100, when writing and reading a second logic state into and from the memory cell 1100. It should be understood that the voltages shown in in FIGS. 16A to 17D are merely illustrative examples, and should not be limited thereto.

Referring first to FIG. 16A, the memory cell 1100 is in a “hold” state, e.g., after the memory cell 1100 is written with a logic 1. As shown, the RWL and WWL are applied with a first supply voltage corresponding to a high logic state (e.g., VDD), thus turning off the MR and MW, respectively. With both the MR and MW being turned off (both write and read paths are cut off), the memory cell 1100, in such a hold state, may hold data written to a gate (capacitance) of the MS (e.g., a logic 1 or VDD). Such a node (the gate of the MS) is sometimes referred to as “SN.” In some embodiments, the WBL and RBL are applied with the first supply voltage (VDD) and a second supply voltage corresponding to a low logic state (e.g., ground or GND), respectively.

Referring next to FIGS. 16B and 16C, the memory cell 1100 is in a “write 0” state, e.g., writing a logic 0 to the memory cell 1100. As shown in FIG. 16B, the voltage applied to the WWL may transition from VDD to GND and the voltage applied to the WBL may transition from VDD to GND (with the RBL and RWL being applied with GND and VDD, respectively). The MW is thus turned on, conducting a write path 1601 from the gate of the MS to the WBL. As such, data of a logic 0 can be written to the gate (capacitance) of the MS, causing a voltage of SN to be equal to about GND. Next in FIG. 16C, the voltage applied to the WWL may transition from GND to VDD and the voltage applied to the WBL may transition from GND to VDD (with the RBL and RWL being applied with GND and VDD, respectively), which turns off the MW. Accordingly, the voltage of SN may be pulled up a bit from GND, e.g., GND+ΔV. ΔV may be a voltage drop induced across the gate of MW and the source/drain of MW.

Referring then to FIG. 16D, the memory cell 1100 is in a “read 0” state, e.g., after being written with a logic 0. As shown, the voltage applied to the gate of the MW (WWL) may remain at VDD, while a voltage applied to the gate of the MR (RWL) may transition from VDD to GND. Accordingly, the MR is turned on, conducting a read path 1603 from one of the source/drain of the MS/WBL (VDD), through the MS and MR, and to the RBL. In some embodiments, with the voltage of SN remaining at GND+ΔV, a voltage present on the RBL may become VDD−ΔV. The RBL can be operatively connected to a sense amplifier to detect such a voltage level so as to determine that the data stored in the memory cell 1100 is a logic 0.

Different from the operations of FIGS. 16A-D where a logic 0 is written to and read from the memory cell 1100, FIGS. 17A-D illustrate operations statuses of the memory cell 1100 when a logic 1 is written to and read from the memory cell 1100.

Referring first to FIG. 17A, the memory cell 1100 is in a “hold” state, e.g., after the memory cell 1100 is written with a logic 0. As shown, the RWL and WWL are applied with a first supply voltage corresponding to a high logic state (e.g., VDD), thus turning off the MR and MW, respectively. With both the MR and MW being turned off (both write and read paths are cut off), the memory cell 1100, in such a hold state, may hold data written to a gate (capacitance) of the MS (e.g., a logic 0 or GND). In some embodiments, the WBL and RBL are applied with the first supply voltage (VDD) and a second supply voltage corresponding to a low logic state (e.g., GND), respectively.

Referring next to FIGS. 17B and 17C, the memory cell 1100 is in a “write 1” state, e.g., writing a logic 1 to the memory cell 1100. As shown in FIG. 17B, the voltage applied to the WWL may transition from VDD to GND (with the WBL and RWL being both applied with VDD, and the RBL being applied with GND). The MW is thus turned on, conducting a write path 1701 from the WBL to the gate of the MS. As such, data of a logic 1 can be written to the gate (capacitance) of the MS, causing a voltage of SN to be equal to about VDD. Next in FIG. 17C, the voltage applied to the WWL may transition from GND to VDD and the voltage applied to the WBL may remain at VDD (with the RBL being applied with GND), which turns off the MW. Accordingly, the voltage of SN may be pulled up a bit from VDD, e.g., VDD+ΔV. ΔV may be a voltage drop induced across the gate of MW and the source/drain of MW.

Referring then to FIG. 17D, the memory cell 1100 is in a “read 1” state, e.g., after being written with a logic 1. As shown, the voltage applied to the gate of the MW (WWL) may remain at VDD, while a voltage applied to the gate of the MR (RWL) may transition from VDD to GND. Accordingly, the MR is turned on. Since the MS is turned off (with the voltage of SN present at around VDD), the voltage present on the RBL may remain at GND. The RBL can be operatively connected to a sense amplifier to detect such a voltage level so as to determine that the data stored in the memory cell 1100 is a logic 0.

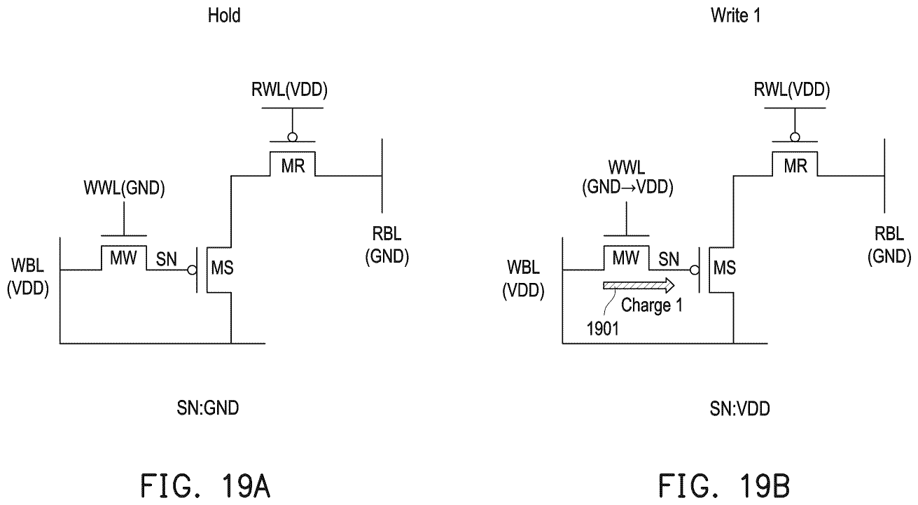

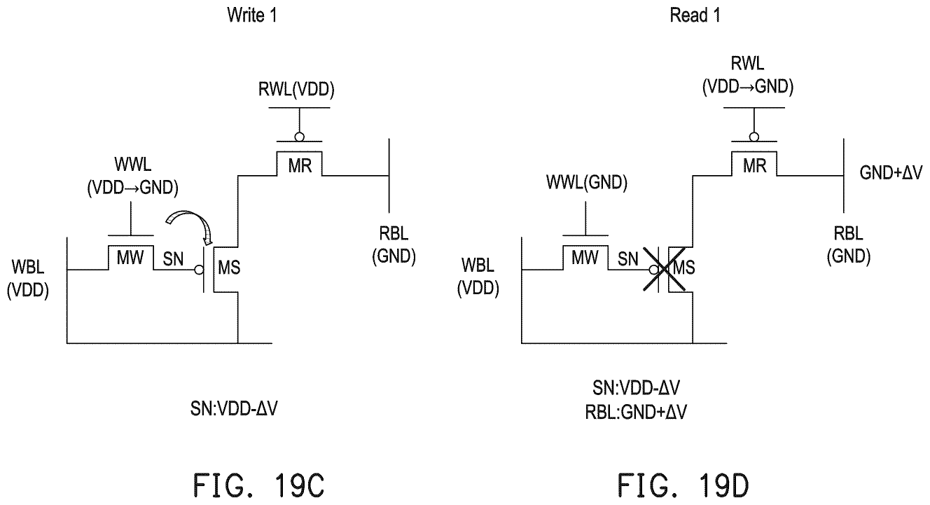

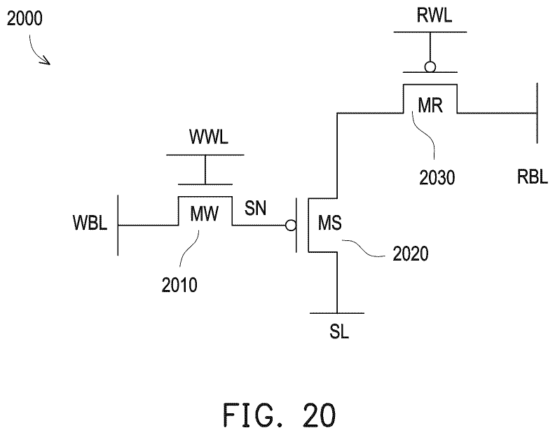

FIGS. 18A to 18D and 19A to 19D illustrate various example operation statuses of the memory cell 1200 (FIG. 12), in accordance with various embodiments. For example, FIGS. 18A to 18D illustrate the operation statuses of the memory cell 1200, when writing and reading a first logic state into and from the memory cell 1200; and FIGS. 19A to 19D illustrate the operation statuses of the memory cell 1200, when writing and reading a second logic state into and from the memory cell 1200. It should be understood that the voltages shown in in FIGS. 18A to 19D are merely illustrative examples, and should not be limited thereto.

Referring first to FIG. 18A, the memory cell 1200 is in a “hold” state, e.g., after the memory cell 1200 is written with a logic 1. As shown, the RWL and WWL are applied with a first supply voltage corresponding to a high logic state (e.g., VDD) and a second supply voltage corresponding to a low logic state (e.g., GND), thus turning off the MR and MW, respectively. With both the MR and MW being turned off (both write and read paths are cut off), the memory cell 1200, in such a hold state, may hold data written to a gate (capacitance) of the MS (e.g., a logic 1 or VDD). Such a node (the gate of the MS) is sometimes referred to as “SN.” In some embodiments, the WBL and RBL are applied with the first supply voltage (VDD) and the second supply voltage (GND), respectively.

Referring next to FIGS. 18B and 18C, the memory cell 1200 is in a “write 0” state, e.g., writing a logic 0 to the memory cell 1200. As shown in FIG. 18B, the voltage applied to the WWL may transition from GND to VDD and the voltage applied to the WBL may transition from VDD to GND (with the RBL and RWL being applied with GND and VDD, respectively). The MW is thus turned on, conducting a write path 1801 from the gate of the MS to the W/RBL. As such, data of a logic 0 can be written to the gate (capacitance) of the MS, causing a voltage of SN to be equal to about GND. Next in FIG. 18C, the voltage applied to the WWL may transition from VDD to GND and the voltage applied to the WBL may transition from GND to VDD (with the RWL and RBL being applied with VDD and GND, respectively), which turns off the MW. Accordingly, the voltage of SN may be pulled down a bit from GND, e.g., GND−ΔV. ΔV may be a voltage drop induced across the gate of MW and the source/drain of MW.

Referring then to FIG. 18D, the memory cell 1200 is in a “read 0” state, e.g., after being written with a logic 0. As shown, the voltage applied to the gate of the MW (WWL) may remain at GND, while a voltage applied to the gate of the MR (RWL) may transition from VDD to GND. Accordingly, the MR is turned on, conducting a read path 1803 from one of the source/drain of the MS/WBL (VDD), through the MS and MR, and to the RBL. In some embodiments, with the voltage of SN remaining at GND−ΔV, a voltage present on the RBL may become VDD. The RBL can be operatively connected to a sense amplifier to detect such a voltage level so as to determine that the data stored in the memory cell 1200 is a logic 0.

Different from the operations of FIGS. 18A-D where a logic 0 is written to and read from the memory cell 1200, FIGS. 19A-D illustrate operations statuses of the memory cell 1200 when a logic 1 is written to and read from the memory cell 1200.

Referring first to FIG. 19A, the memory cell 1200 is in a “hold” state, e.g., after the memory cell 1200 is written with a logic 1. As shown, the RWL and WWL are applied with a first supply voltage corresponding to a high logic state (e.g., VDD) and a second supply voltage corresponding to a low logic state (e.g., GND), thus turning off the MR and MW, respectively. With both the MR and MW being turned off (both write and read paths are cut off), the memory cell 1200, in such a hold state, may hold data written to a gate (capacitance) of the MS (e.g., a logic 0 or GND). In some embodiments, the WBL and RBL are applied with the first supply voltage (VDD) and the second supply voltage (GND), respectively.

Referring next to FIGS. 19B and 19C, the memory cell 1200 is in a “write 1” state, e.g., writing a logic 1 to the memory cell 1200. As shown in FIG. 19B, the voltage applied to the WWL may transition from GND to VDD (with the RWL and WBL being both applied with VDD and the RBL being applied with GND). The MW is thus turned on, conducting a write path 1901 from the WBL to the gate of the MS. As such, data of a logic 1 can be written to the gate (capacitance) of the MS, causing a voltage of SN to be equal to about VDD. Next in FIG. 19C, the voltage applied to the WWL may transition from VDD to GND and the voltage applied to the WBL may remain at VDD (with the RWL and WBL being both applied with VDD and the RBL being applied with GND), which turns off the MW. Accordingly, the voltage of SN may be pulled down a bit from VDD, e.g., VDD−ΔV. ΔV may be a voltage drop induced across the gate of MW and the source/drain of MW.

Referring then to FIG. 19D, the memory cell 1200 is in a “read 1” state, e.g., after being written with a logic 1. As shown, the voltage applied to the gate of the MW (WWL) may remain at GND, while a voltage applied to the gate of the MR (RWL) may transition from VDD to GND. Accordingly, the MR is turned on. Since the MS is turned off (with the voltage of SN present at around VDD), the voltage present on the RBL may remain at around GND. The RBL can be operatively connected to a sense amplifier to detect such a voltage level so as to determine that the data stored in the memory cell 1200 is a logic 1.

In various embodiments of the present disclosure, transistors constituting the memory cell (e.g., 100, 200, 1100, 1200), as disclosed herein, can be configured in any of various architectures. For example, in the discussions above, the transistors may be formed as a FinFET architecture where different transistors may have their respective channels (e.g., fins) disposed in parallel with one another and in the same device layer/level. In some other embodiments, the transistors of the disclosed memory cell can be placed at two or more vertically aligned device levels, which is sometimes referred to as a complementary field-effect transistor (CFET) architecture. For example, the transistors having different conductive types may be formed in respective device levels.

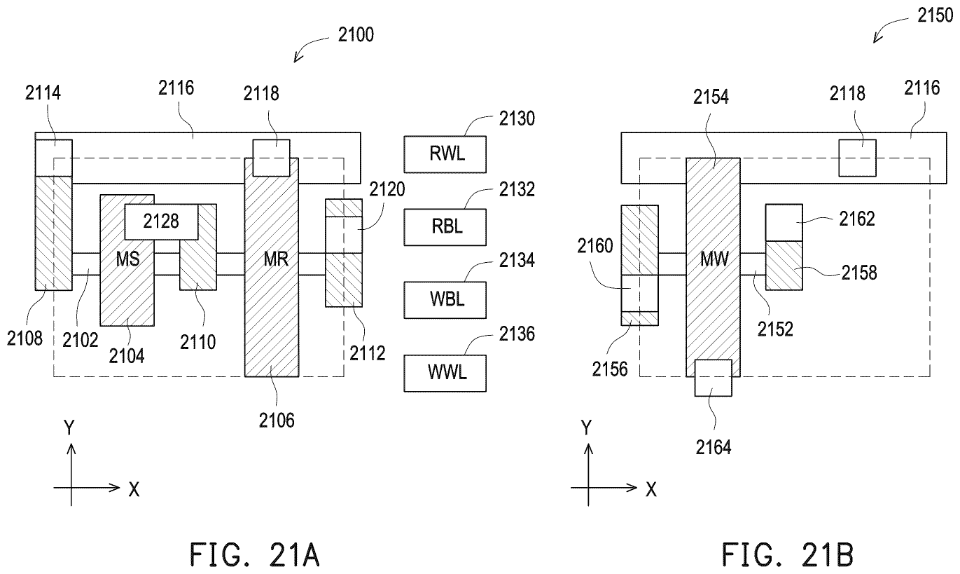

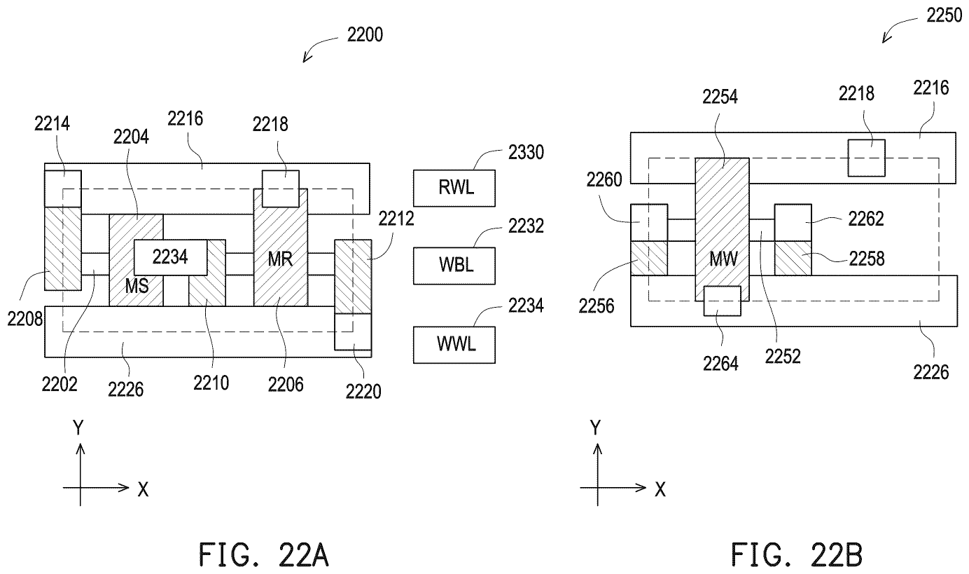

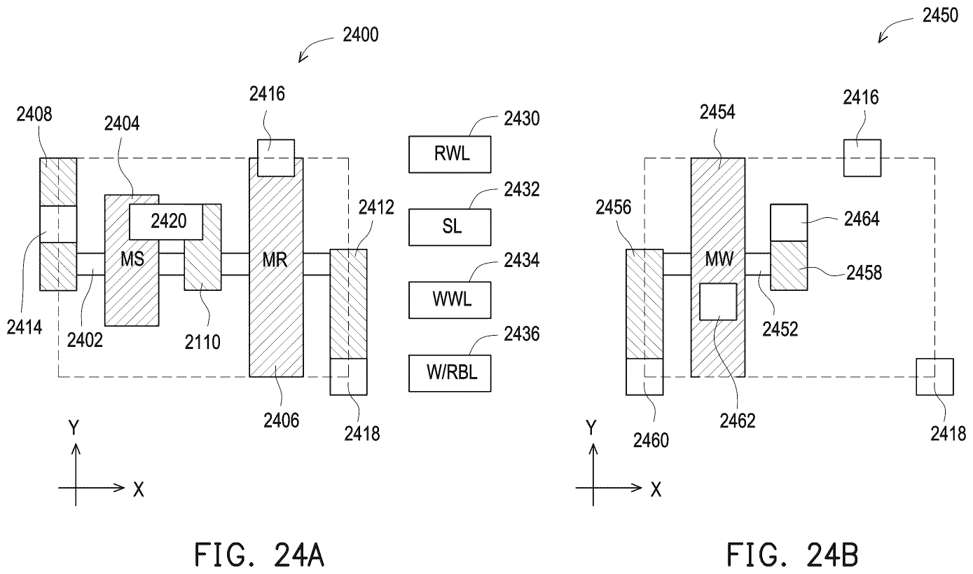

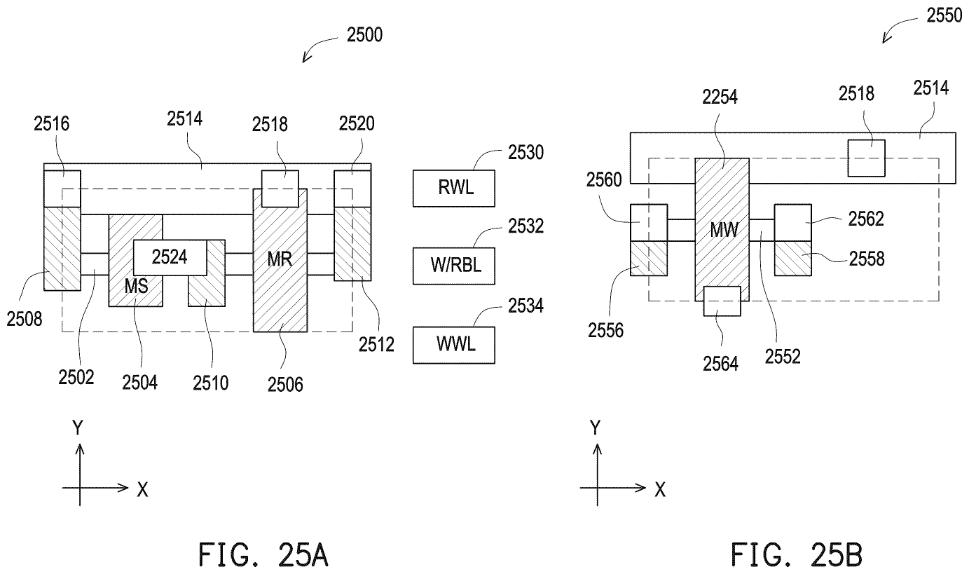

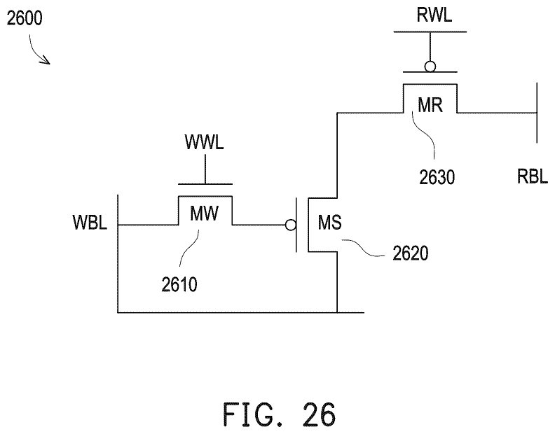

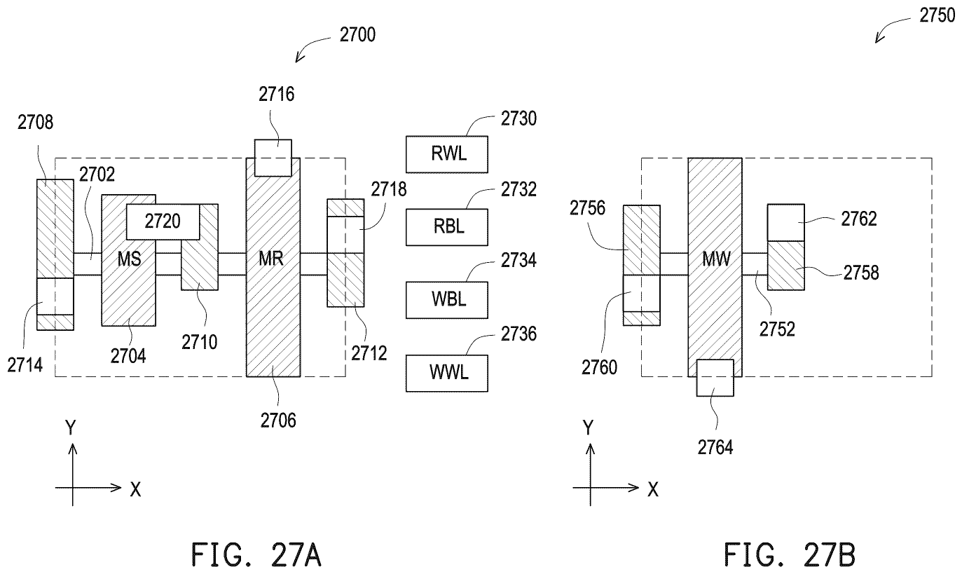

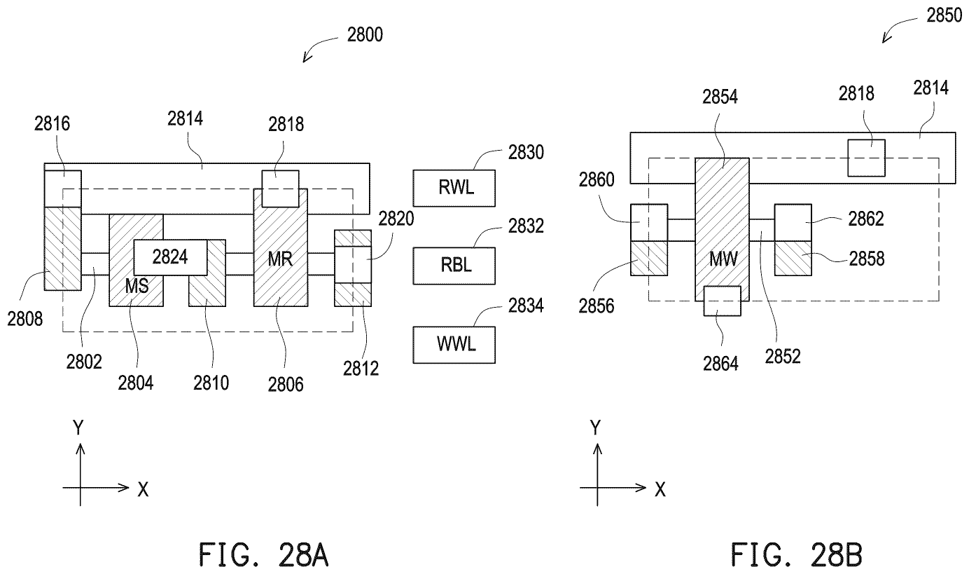

FIGS. 20, 23, and 26 depict example circuit diagrams of memory cells 2000, 2300, and 2600, respectively, in accordance with various embodiments. FIGS. 21A and 21B illustrate first example layouts for the memory cell 2000 configured in the CFET architecture; FIGS. 22A and 22B illustrate second example layouts for the memory cell 2000 configured in the CFET architecture; FIGS. 24A and 24B illustrate first example layouts for the memory cell 2300 configured in the CFET architecture; FIGS. 25A and 25B illustrate second example layouts for the memory cell 2300 configured in the CFET architecture; FIGS. 27A and 27B illustrate first example layouts for the memory cell 2600 configured in the CFET architecture; and FIGS. 28A and 28B illustrate second example layouts for the memory cell 2600 configured in the CFET architecture.

Referring first to FIG. 20, transistors MW 2010, MS 2020 and MR 2030 of the memory cell 2000 may be operatively coupled to one another similarly to the memory cell 100 (FIG. 1), 200 (FIG. 2), 1100 (FIG. 11), or 1200 (FIG. 12). In some embodiments, the transistors MW 2010, MS 2020, and MR 2030 may be operatively coupled to one or more access lines as shown in FIG. 20. For example, the MW 2010 and MR 2030 are gated by WWL and RWL, respectively, with MW 2010's one source/drain and MR 2030's one source/drain connected to WBL and RBL, respectively. A gate of the MS 2020 is connected to the other source/drain of the MW 2010, and the MS 2020's first source/drain and second source/drain are connected to SL and the other source/drain of the MR 2030, respectively.

FIGS. 21A and 21B illustrate a first set of layouts 2100 and 2150 that can be collectively utilized to form the memory cell 2000. Specifically, the layout 2100 of FIG. 21A is configured to form at least the MS 2020 and MR 2030; and the layout 2150 of FIG. 21B is configured to form at least the MW 2010. The layouts 2100 and 2150 correspond to respectively different physical device levels, in some embodiments.

For example, the layout 2100 includes pattern 2102 extending along the X direction. The pattern 2102 is configured to form an active region (e.g., a fin structure, a well, a protruding structure having alternately stacked silicon and silicon germanium layers, etc., which is sometimes referred to as an oxide diffusion (OD) region) over a substrate. The layout 2100 includes patterns 2104 and 2106 extending along the Y direction. The patterns 2104 to 2106 are each configured to form a gate structure (e.g., a polysilicon gate, a metal gate, etc.) over the active regions. Accordingly, the pattern 2102 may be referred to as an active region, and the patterns 2104 to 2106 may each be referred to as a gate structure.

In some embodiments, each of the gate structures can overlay at least one active region to form a transistor. For example in FIG. 21A, the gate structure 2104, together with the active region 2102, can form the MS 2020 (FIG. 20); and the gate structure 2106, together with the active region 2102, can form the MR 2030. Specifically, the gate structures 2104 and 2106 can operatively serve as gates of the MS 2020 and MR 2030, respectively. Further, the portions of each active region on opposite sides of the overlaying gate structure (i.e., the portions not overlaid by the gate structure) can form the corresponding transistor's source and drain, respectively.

The layout 2100 further includes patterns 2108, 2110, and 2112 extending along the Y direction and disposed between adjacent gate structures (i.e., overlaying the source or drain of a transistor). The patterns 2108 to 2112 are each configured to form a middle-end interconnect structure (sometimes referred to as “MD”). Accordingly, the patterns 2108, 2110, and 2112 may each be referred to as an MD. Such an MD is generally configured to electrically connect the source or drain of a transistor to the source or drain of another transistor or to a supply voltage.

For example, the MD 2108 can connect one source/drain of the MS 2020 to an interconnect structure that carries a supply voltage of VDD (formed by pattern 2116, hereinafter interconnect structure 2116) through a via structure 2114. The interconnect structure 2116 may correspond to the SL shown in FIG. 20, according to some embodiments. The gate structure 2106 (the gate of the MR 2030) may be connected to another interconnect structure (formed by pattern 2130, hereinafter interconnect structure 2130) through a via structure 2118. The interconnect structure 2130 may correspond to the RWL show in FIG. 20, according to some embodiments. The MD 2112 can connect one source/drain of the MR 2030 to yet another interconnect structure (formed by pattern 2132, hereinafter interconnect structure 2132) through a via structure 2120. The interconnect structure 2132 may correspond to the RBL show in FIG. 20, according to some embodiments. The layout 2100 further includes a pattern 2128 extending along the X direction to connect the gate structure 2104 (the gate of the MS 2020) to an component in another device level (e.g., one source/drain of the MW 2010), which will be discussed as follows.

Similarly in FIG. 21B, the layout 2150 includes pattern 2152 extending along the X direction. The pattern 2152 is configured to form an active region (e.g., a fin structure, a well, a protruding structure having alternately stacked silicon and silicon germanium layers, etc., which is sometimes referred to as an oxide diffusion (OD) region) over a substrate. The layout 2150 includes pattern 2154 extending along the Y direction. The pattern 2154 is configured to form a gate structure (e.g., a polysilicon gate, a metal gate, etc.) over the active regions. Accordingly, the pattern 2152 may be referred to as an active region, and the pattern 2154 may be referred to as a gate structure.

In some embodiments, the gate structure 2154, together with the active region 2152, can form the MW 2010 (FIG. 20). Specifically, the gate structure 2154 can operatively serve as a gate of the MW 2010. Further, the portions of each active region on opposite sides of the overlaying gate structure (i.e., the portions not overlaid by the gate structure) can form the corresponding transistor's source and drain, respectively.

The layout 2150 further includes patterns 2156 and 2158 extending along the Y direction and disposed between adjacent gate structures (i.e., overlaying the source or drain of a transistor). The patterns 2156 to 2158 are each configured to form a middle-end interconnect structure (sometimes referred to as “MD”). Accordingly, the patterns 2156 and 2158 may each be referred to as an MD. Such an MD is generally configured to electrically connect the source or drain of a transistor to the source or drain of another transistor or to a supply voltage.

For example, the MD 2156 can connect one source/drain of the MW 2010 to yet another interconnect structure (formed by pattern 2134, hereinafter interconnect structure 2134) through a via structure 2160. The interconnect structure 2134 may correspond to the WBL shown in FIG. 20, according to some embodiments. The MD 2158 can connect the other source/drain of the MW 2010 to the gate structure 2104 (the gate of the MS 2020) disposed in the other device level through a via structure 2162. The gate structure 2154 (the gate of the MW 2010) may be connected to yet another interconnect structure (formed by pattern 2136, hereinafter interconnect structure 2136) that operatively serves as the WWL of FIG. 20 through a via structure 2164.

In some embodiments, the interconnect structures 2130 (RWL), 2132 (RBL), 2314 (WBL), and 2136 (WWL) may be formed in a device level different than the device level formed by the layout 2100 or 2150. For example, the device level having the interconnect structures 2130 to 2136, which can be implemented as one or more metallization layers/levels, can be formed above both the device levels respectively corresponding to the layouts 2100 and 2150. In another example, the device level having the interconnect structures 2130 to 2136, which can be implemented as one or more metallization layers/levels, can be formed between the device levels respectively corresponding to the layouts 2100 and 2150.

FIGS. 22A and 22B illustrate a second set of layouts 2200 and 2250 that can be collectively utilized to form the memory cell 2000. Specifically, the layout 2200 of FIG. 22A is configured to form at least the MS 2020 and MR 2030; and the layout 2250 of FIG. 22B is configured to form at least the MW 2010. The layouts 2200 and 2250 correspond to respectively different physical device levels, in some embodiments.

For example, the layout 2200 includes pattern 2202 extending along the X direction. The pattern 2202 is configured to form an active region (e.g., a fin structure, a well, a protruding structure having alternately stacked silicon and silicon germanium layers, etc., which is sometimes referred to as an oxide diffusion (OD) region) over a substrate. The layout 2200 includes patterns 2204 and 2206 extending along the Y direction. The patterns 2204 to 2206 are each configured to form a gate structure (e.g., a polysilicon gate, a metal gate, etc.) over the active regions. Accordingly, the pattern 2202 may be referred to as an active region, and the patterns 2204 to 2206 may each be referred to as a gate structure.

In some embodiments, each of the gate structures can overlay at least one active region to form a transistor. For example in FIG. 22A, the gate structure 2204, together with the active region 2202, can form the MS 2020 (FIG. 20); and the gate structure 2206, together with the active region 2202, can form the MR 2030. Specifically, the gate structures 2204 and 2206 can operatively serve as gates of the MS 2020 and MR 2030, respectively. Further, the portions of each active region on opposite sides of the overlaying gate structure (i.e., the portions not overlaid by the gate structure) can form the corresponding transistor's source and drain, respectively.

The layout 2200 further includes patterns 2208, 2210, and 2212 extending along the Y direction and disposed between adjacent gate structures (i.e., overlaying the source or drain of a transistor). The patterns 2208 to 2212 are each configured to form a middle-end interconnect structure (sometimes referred to as “MD”). Accordingly, the patterns 2208, 2210, and 2212 may each be referred to as an MD. Such an MD is generally configured to electrically connect the source or drain of a transistor to the source or drain of another transistor or to a supply voltage.

For example, the MD 2208 can connect one source/drain of the MS 2020 to an interconnect structure that carries a supply voltage of VDD (formed by pattern 2216, hereinafter interconnect structure 2216) through a via structure 2214. The interconnect structure 2216 may correspond to the SL shown in FIG. 20, according to some embodiments. The gate structure 2206 (the gate of the MR 2030) may be connected to another interconnect structure (formed by pattern 2230, hereinafter interconnect structure 2230) through a via structure 2218. The interconnect structure 2230 may correspond to the RWL show in FIG. 20, according to some embodiments. The MD 2212 can connect one source/drain of the MR 2030 to yet another interconnect structure (formed by pattern 2226, hereinafter interconnect structure 2226) through a via structure 2220. The interconnect structure 2226 may correspond to the RBL show in FIG. 20, according to some embodiments. The layout 2200 further includes a pattern 2234 extending along the X direction to connect the gate structure 2204 (the gate of the MS 2020) to an component in another device level (e.g., one source/drain of the MW 2010), which will be discussed as follows.

Similarly in FIG. 22B, the layout 2250 includes pattern 2252 extending along the X direction. The pattern 2252 is configured to form an active region (e.g., a fin structure, a well, a protruding structure having alternately stacked silicon and silicon germanium layers, etc., which is sometimes referred to as an oxide diffusion (OD) region) over a substrate. The layout 2250 includes pattern 2254 extending along the Y direction. The pattern 2254 is configured to form a gate structure (e.g., a polysilicon gate, a metal gate, etc.) over the active regions. Accordingly, the pattern 2252 may be referred to as an active region, and the pattern 2254 may be referred to as a gate structure.

In some embodiments, the gate structure 2254, together with the active region 2252, can form the MW 2010 (FIG. 20). Specifically, the gate structure 2254 can operatively serve as a gate of the MW 2010. Further, the portions of each active region on opposite sides of the overlaying gate structure (i.e., the portions not overlaid by the gate structure) can form the corresponding transistor's source and drain, respectively.

The layout 2250 further includes patterns 2256 and 2258 extending along the Y direction and disposed between adjacent gate structures (i.e., overlaying the source or drain of a transistor). The patterns 2256 to 2258 are each configured to form a middle-end interconnect structure (sometimes referred to as “MD”). Accordingly, the patterns 2256 to 2258 may each be referred to as an MD. Such an MD is generally configured to electrically connect the source or drain of a transistor to the source or drain of another transistor or to a supply voltage.

For example, the MD 2256 can connect one source/drain of the MW 2010 to yet another interconnect structure (formed by pattern 2232, hereinafter interconnect structure 2232) through a via structure 2260. The interconnect structure 2232 may correspond to the WBL shown in FIG. 20, according to some embodiments. The MD 2258 can connect the other source/drain of the MW 2010 to the gate structure 2204 (the gate of the MS 2020) disposed in the other device level through a via structure 2262. The gate structure 2254 (the gate of the MW 2010) may be connected to yet another interconnect structure (formed by pattern 2234, hereinafter interconnect structure 2234) that operatively serves as the WWL of FIG. 20 through a via structure 2264.

In some embodiments, the interconnect structures 2230 (RWL), 2232 (WBL), and 2234 (WWL) may be formed in a device level different than the device level formed by the layout 2200 or 2250. For example, the device level having the interconnect structures 2230 to 2234, which can be implemented as one or more metallization layers/levels, can be formed above both the device levels respectively corresponding to the layouts 2200 and 2250. In another example, the device level having the interconnect structures 2230 to 2234, which can be implemented as one or more metallization layers/levels, can be formed between the device levels respectively corresponding to the layouts 2200 and 2250.

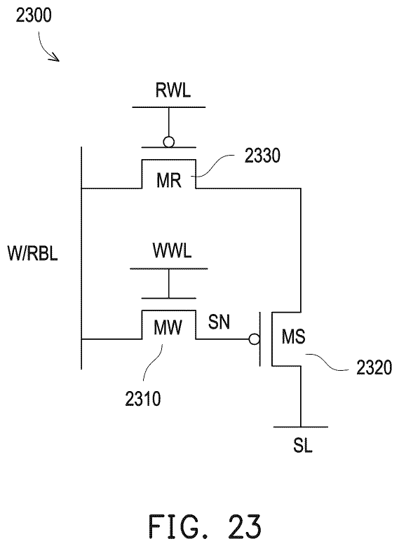

Referring next to FIG. 23, transistors MW 2310, MS 2320 and MR 2330 of the memory cell 2300 may be operatively coupled to one another similarly to the memory cell 100 (FIG. 1), 200 (FIG. 2), 1100 (FIG. 11), or 1200 (FIG. 12). Further, the transistors MW 2310, MS 2320, and MR 2330 may be operatively coupled to one or more access lines in similar fashion to the memory cell 100 (FIG. 1) or 200 (FIG. 2). For example, the MW 2310 and MR 2330 are gated by WWL and RWL, respectively, with MW 2310's one source/drain and MR 2330's one source/drain both connected to W/RBL. A gate of the MS 2320 is connected to the other source/drain of the MW 2310, and the MS 2320's first source/drain and second source/drain are connected to SL and the other source/drain of the MR 2330, respectively.

FIGS. 24A and 24B illustrate a first set of layouts 2400 and 2450 that can be collectively utilized to form the memory cell 2300. Specifically, the layout 2400 of FIG. 24A is configured to form at least the MS 2320 and MR 2330; and the layout 2450 of FIG. 24B is configured to form at least the MW 2310. The layouts 2400 and 2450 correspond to respectively different physical device levels, in some embodiments.

For example, the layout 2400 includes pattern 2402 extending along the X direction. The pattern 2402 is configured to form an active region (e.g., a fin structure, a well, a protruding structure having alternately stacked silicon and silicon germanium layers, etc., which is sometimes referred to as an oxide diffusion (OD) region) over a substrate. The layout 2400 includes patterns 2404 and 2406 extending along the Y direction. The patterns 2404 to 2406 are each configured to form a gate structure (e.g., a polysilicon gate, a metal gate, etc.) over the active regions. Accordingly, the pattern 2402 may be referred to as an active region, and the patterns 2404 to 2406 may each be referred to as a gate structure.

In some embodiments, each of the gate structures can overlay at least one active region to form a transistor. For example in FIG. 24A, the gate structure 2404, together with the active region 2402, can form the MS 2320 (FIG. 23); and the gate structure 2406, together with the active region 2402, can form the MR 2330. Specifically, the gate structures 2404 and 2406 can operatively serve as gates of the MS 2320 and MR 2330, respectively. Further, the portions of each active region on opposite sides of the overlaying gate structure (i.e., the portions not overlaid by the gate structure) can form the corresponding transistor's source and drain, respectively.

The layout 2400 further includes patterns 2408, 2410, and 2412 extending along the Y direction and disposed between adjacent gate structures (i.e., overlaying the source or drain of a transistor). The patterns 2408 to 2412 are each configured to form a middle-end interconnect structure (sometimes referred to as “MD”). Accordingly, the patterns 2408, 2410, and 2412 may each be referred to as an MD. Such an MD is generally configured to electrically connect the source or drain of a transistor to the source or drain of another transistor or to a supply voltage.

For example, the MD 2408 can connect one source/drain of the MS 2320 to an interconnect structure that carries a supply voltage of VDD (formed by pattern 2433, hereinafter interconnect structure 2432) through a via structure 2414. The interconnect structure 2432 may correspond to the SL shown in FIG. 23, according to some embodiments. The gate structure 2406 (the gate of the MR 2330) may be connected to another interconnect structure (formed by pattern 2430, hereinafter interconnect structure 2430) through a via structure 2416. The interconnect structure 2430 may correspond to the RWL show in FIG. 20, according to some embodiments. The MD 2412 can connect one source/drain of the MR 2030 to yet another interconnect structure (formed by pattern 2436, hereinafter interconnect structure 2436) through a via structure 2418. The interconnect structure 2436 may correspond to the W/RBL show in FIG. 23, according to some embodiments. The layout 2200 further includes a pattern 2420 extending along the X direction to connect the gate structure 2404 (the gate of the MS 2320) to an component in another device level (e.g., one source/drain of the MW 2310), which will be discussed as follows.

Similarly in FIG. 24B, the layout 2450 includes pattern 2452 extending along the X direction. The pattern 2452 is configured to form an active region (e.g., a fin structure, a well, a protruding structure having alternately stacked silicon and silicon germanium layers, etc., which is sometimes referred to as an oxide diffusion (OD) region) over a substrate. The layout 2450 includes pattern 2454 extending along the Y direction. The pattern 2454 is configured to form a gate structure (e.g., a polysilicon gate, a metal gate, etc.) over the active regions. Accordingly, the pattern 2452 may be referred to as an active region, and the pattern 2454 may be referred to as a gate structure.

In some embodiments, the gate structure 2454, together with the active region 2452, can form the MW 2310 (FIG. 23). Specifically, the gate structure 2454 can operatively serve as a gate of the MW 2310. Further, the portions of each active region on opposite sides of the overlaying gate structure (i.e., the portions not overlaid by the gate structure) can form the corresponding transistor's source and drain, respectively.

The layout 2450 further includes patterns 2456 and 2458 extending along the Y direction and disposed between adjacent gate structures (i.e., overlaying the source or drain of a transistor). The patterns 2456 and 2458 are each configured to form a middle-end interconnect structure (sometimes referred to as “MD”). Accordingly, the patterns 2456 to 2458 may each be referred to as an MD. Such an MD is generally configured to electrically connect the source or drain of a transistor to the source or drain of another transistor or to a supply voltage.

For example, the MD 2456 connect one source/drain of the MW 2310 to the interconnect structure 2436 (W/RBL) through a via structure 2460. The MD 2458 can connect the other source/drain of the MW 2310 to the gate structure 2404 (the gate of the MS 2320) disposed in the other device level through a via structure 2464. The gate structure 2454 (the gate of the MW 2310), through a via structure 2462, may be connected to yet another interconnect structure (formed by pattern 2434, hereinafter interconnect structure 2434) that operatively serves as the WWL of FIG. 23.

In some embodiments, the interconnect structures 2430 (RWL), 2432 (SL), 2434 (WWL), and 2436 (W/RBL) may be formed in a device level different than the device level formed by the layout 2400 or 2450. For example, the device level having the interconnect structures 2430 to 2436, which can be implemented as one or more metallization layers/levels, can be formed above both the device levels respectively corresponding to the layouts 2400 and 2450. In another example, the device level having the interconnect structures 2430 to 2436, which can be implemented as one or more metallization layers/levels, can be formed between the device levels respectively corresponding to the layouts 2400 and 2450.

FIGS. 25A and 25B illustrate a second set of layouts 2500 and 2550 that can be collectively utilized to form the memory cell 2300. Specifically, the layout 2500 of FIG. 25A is configured to form at least the MS 2320 and MR 2330; and the layout 2550 of FIG. 25B is configured to form at least the MW 2310. The layouts 2500 and 2550 correspond to respectively different physical device levels, in some embodiments.

For example, the layout 2500 includes pattern 2502 extending along the X direction. The pattern 2502 is configured to form an active region (e.g., a fin structure, a well, a protruding structure having alternately stacked silicon and silicon germanium layers, etc., which is sometimes referred to as an oxide diffusion (OD) region) over a substrate. The layout 2500 includes patterns 2504 and 2506 extending along the Y direction. The patterns 2504 to 2506 are each configured to form a gate structure (e.g., a polysilicon gate, a metal gate, etc.) over the active regions. Accordingly, the pattern 2502 may be referred to as an active region, and the patterns 2504 to 2506 may each be referred to as a gate structure.

In some embodiments, each of the gate structures can overlay at least one active region to form a transistor. For example in FIG. 25A, the gate structure 2504, together with the active region 2502, can form the MS 2320 (FIG. 23); and the gate structure 2506, together with the active region 2502, can form the MR 2330. Specifically, the gate structures 2504 and 2506 can operatively serve as gates of the MS 2320 and MR 2330, respectively. Further, the portions of each active region on opposite sides of the overlaying gate structure (i.e., the portions not overlaid by the gate structure) can form the corresponding transistor's source and drain, respectively.

The layout 2500 further includes patterns 2508, 2510, and 2512 extending along the Y direction and disposed between adjacent gate structures (i.e., overlaying the source or drain of a transistor). The patterns 2508 to 2512 are each configured to form a middle-end interconnect structure (sometimes referred to as “MD”). Accordingly, the patterns 2508, 2510, and 2512 may each be referred to as an MD. Such an MD is generally configured to electrically connect the source or drain of a transistor to the source or drain of another transistor or to a supply voltage.

For example, the MD 2508 can connect one source/drain of the MS 2320 to an interconnect structure that carries a supply voltage of VDD (formed by pattern 2514, hereinafter interconnect structure 2514) through a via structure 2516. The interconnect structure 2514 may correspond to the SL shown in FIG. 23, according to some embodiments. The gate structure 2506 (the gate of the MR 2330) may be connected to another interconnect structure (formed by pattern 2530, hereinafter interconnect structure 2530) through a via structure 2518. The interconnect structure 2530 may correspond to the RWL show in FIG. 23, according to some embodiments. The MD 2512 can connect one source/drain of the MR 2330 to yet another interconnect structure (formed by pattern 2532, hereinafter interconnect structure 2532) through a via structure 2520. The interconnect structure 2532 may correspond to the W/RBL show in FIG. 23, according to some embodiments. The layout 2500 further includes a pattern 2524 extending along the X direction to connect the gate structure 2504 (the gate of the MS 2320) to an component in another device level (e.g., one source/drain of the MW 2310), which will be discussed as follows.

Similarly in FIG. 25B, the layout 2550 includes pattern 2552 extending along the X direction. The pattern 2552 is configured to form an active region (e.g., a fin structure, a well, a protruding structure having alternately stacked silicon and silicon germanium layers, etc., which is sometimes referred to as an oxide diffusion (OD) region) over a substrate. The layout 2550 includes pattern 2554 extending along the Y direction. The pattern 2554 is configured to form a gate structure (e.g., a polysilicon gate, a metal gate, etc.) over the active regions. Accordingly, the pattern 2552 may be referred to as an active region, and the pattern 2554 may be referred to as a gate structure.

In some embodiments, the gate structure 2554, together with the active region 2552, can form the MW 2310 (FIG. 23). Specifically, the gate structure 2554 can operatively serve as a gate of the MW 2310. Further, the portions of each active region on opposite sides of the overlaying gate structure (i.e., the portions not overlaid by the gate structure) can form the corresponding transistor's source and drain, respectively.

The layout 2550 further includes patterns 2556 and 2558 extending along the Y direction and disposed between adjacent gate structures (i.e., overlaying the source or drain of a transistor). The patterns 2556 to 2558 are each configured to form a middle-end interconnect structure (sometimes referred to as “MD”). Accordingly, the patterns 2556 to 2558 may each be referred to as an MD. Such an MD is generally configured to electrically connect the source or drain of a transistor to the source or drain of another transistor or to a supply voltage.

For example, the MD 2556 can connect one source/drain of the MW 2310 to the interconnect structure 2532 (W/RBL) through a via structure 2560. The MD 2558 can connect the other source/drain of the MW 2310 to the gate structure 2504 (the gate of the MS 2320) disposed in the other device level through a via structure 2562. The gate structure 2554 (the gate of the MW 2310), through a via structure 2564, may be connected to yet another interconnect structure (formed by pattern 2534, hereinafter interconnect structure 2534) that operatively serves as the WWL of FIG. 23.

In some embodiments, the interconnect structures 2530 (RWL), 2532 (W/RBL), and 2534 (WWL) may be formed in a device level different than the device level formed by the layout 2500 or 2550. For example, the device level having the interconnect structures 2530 to 2534, which can be implemented as one or more metallization layers/levels, can be formed above both the device levels respectively corresponding to the layouts 2500 and 2550. In another example, the device level having the interconnect structures 2530 to 2534, which can be implemented as one or more metallization layers/levels, can be formed between the device levels respectively corresponding to the layouts 2500 and 2550.

Referring then to FIG. 26, transistors MW 2610, MS 2620 and MR 2630 of the memory cell 2600 may be operatively coupled to one another similarly to the memory cell 100 (FIG. 1), 200 (FIG. 2), 1100 (FIG. 11), or 1200 (FIG. 12). Further, the transistors MW 2610, MS 2620, and MR 2630 may be operatively coupled to one or more access lines in similar fashion to the memory cell 1100 (FIG. 11) or 1200 (FIG. 12). For example, the MW 2610 and MR 2630 are gated by WWL and RWL, respectively, with MW 2610's one source/drain and MS 2620's one source/drain both connected to WBL. A gate of the MS 2620 is connected to the other source/drain of the MW 2610, and the MR 2630's first source/drain and second source/drain are connected to RBL and the other source/drain of the MS 2620, respectively.

FIGS. 27A and 27B illustrate a first set of layouts 2700 and 2750 that can be collectively utilized to form the memory cell 2600. Specifically, the layout 2700 of FIG. 27A is configured to form at least the MS 2620 and MR 2630; and the layout 2750 of FIG. 27B is configured to form at least the MW 2610. The layouts 2700 and 2750 correspond to respectively different physical device levels, in some embodiments.

For example, the layout 2700 includes pattern 2702 extending along the X direction. The pattern 2702 is configured to form an active region (e.g., a fin structure, a well, a protruding structure having alternately stacked silicon and silicon germanium layers, etc., which is sometimes referred to as an oxide diffusion (OD) region) over a substrate. The layout 2700 includes patterns 2704 and 2706 extending along the Y direction. The patterns 2704 to 2706 are each configured to form a gate structure (e.g., a polysilicon gate, a metal gate, etc.) over the active regions. Accordingly, the pattern 2702 may be referred to as an active region, and the patterns 2704 to 2706 may each be referred to as a gate structure.

In some embodiments, each of the gate structures can overlay at least one active region to form a transistor. For example in FIG. 27A, the gate structure 2704, together with the active region 2702, can form the MS 2620 (FIG. 26); and the gate structure 2706, together with the active region 2702, can form the MR 2630. Specifically, the gate structures 2704 and 2706 can operatively serve as gates of the MS 2620 and MR 2630, respectively. Further, the portions of each active region on opposite sides of the overlaying gate structure (i.e., the portions not overlaid by the gate structure) can form the corresponding transistor's source and drain, respectively.

The layout 2700 further includes patterns 2708, 2710, and 2712 extending along the Y direction and disposed between adjacent gate structures (i.e., overlaying the source or drain of a transistor). The patterns 2708 to 2712 are each configured to form a middle-end interconnect structure (sometimes referred to as “MD”). Accordingly, the patterns 2708, 2710, and 2712 may each be referred to as an MD. Such an MD is generally configured to electrically connect the source or drain of a transistor to the source or drain of another transistor or to a supply voltage.

For example, the MD 2708 can connect one source/drain of the MS 2620 to an interconnect structure (formed by pattern 2734, hereinafter interconnect structure 2734) through a via structure 2714. The interconnect structure 2734 may correspond to the WBL shown in FIG. 26, according to some embodiments. The gate structure 2706 (the gate of the MR 2630) may be connected to another interconnect structure (formed by pattern 2730, hereinafter interconnect structure 2730) through a via structure 2716. The interconnect structure 2730 may correspond to the RWL show in FIG. 26, according to some embodiments. The MD 2712 can connect one source/drain of the MR 2630 to yet another interconnect structure (formed by pattern 2732, hereinafter interconnect structure 2732) through a via structure 2718. The interconnect structure 2732 may correspond to the RBL show in FIG. 26, according to some embodiments. The layout 2700 further includes a pattern 2720 extending along the X direction to connect the gate structure 2704 (the gate of the MS 2620) to an component in another device level (e.g., one source/drain of the MW 2610), which will be discussed as follows.

Similarly in FIG. 27B, the layout 2750 includes pattern 2752 extending along the X direction. The pattern 2752 is configured to form an active region (e.g., a fin structure, a well, a protruding structure having alternately stacked silicon and silicon germanium layers, etc., which is sometimes referred to as an oxide diffusion (OD) region) over a substrate. The layout 2750 includes pattern 2754 extending along the Y direction. The pattern 2754 is configured to form a gate structure (e.g., a polysilicon gate, a metal gate, etc.) over the active regions. Accordingly, the pattern 2752 may be referred to as an active region, and the pattern 2754 may be referred to as a gate structure.

In some embodiments, the gate structure 2754, together with the active region 2752, can form the MW 2610 (FIG. 26). Specifically, the gate structure 2754 can operatively serve as a gate of the MW 2610. Further, the portions of each active region on opposite sides of the overlaying gate structure (i.e., the portions not overlaid by the gate structure) can form the corresponding transistor's source and drain, respectively.

The layout 2750 further includes patterns 2756 and 2758 extending along the Y direction and disposed between adjacent gate structures (i.e., overlaying the source or drain of a transistor). The patterns 2756 and 2758 are each configured to form a middle-end interconnect structure (sometimes referred to as “MD”). Accordingly, the patterns 2756 to 2758 may each be referred to as an MD. Such an MD is generally configured to electrically connect the source or drain of a transistor to the source or drain of another transistor or to a supply voltage.

For example, the MD 2756 connect one source/drain of the MW 2610 to the interconnect structure 2734 (WBL) through a via structure 2760. The MD 2758 can connect the other source/drain of the MW 2610 to the gate structure 2704 (the gate of the MS 2620) disposed in the other device level through a via structure 2762. The gate structure 2754 (the gate of the MW 2610), through a via structure 2764, may be connected to yet another interconnect structure (formed by pattern 2734, hereinafter interconnect structure 2736) that operatively serves as the WWL of FIG. 26.

In some embodiments, the interconnect structures 2730 (RWL), 2732 (RBL), 2734 (WBL), and 2736 (WWL) may be formed in a device level different than the device level formed by the layout 2700 or 2750. For example, the device level having the interconnect structures 2730 to 2736, which can be implemented as one or more metallization layers/levels, can be formed above both the device levels respectively corresponding to the layouts 2700 and 2750. In another example, the device level having the interconnect structures 2730 to 2736, which can be implemented as one or more metallization layers/levels, can be formed between the device levels respectively corresponding to the layouts 2700 and 2750.

FIGS. 28A and 28B illustrate a second set of layouts 2800 and 2850 that can be collectively utilized to form the memory cell 2600. Specifically, the layout 2800 of FIG. 28A is configured to form at least the MS 2620 and MR 2630; and the layout 2850 of FIG. 28B is configured to form at least the MW 2610. The layouts 2800 and 2850 correspond to respectively different physical device levels, in some embodiments.

For example, the layout 2800 includes pattern 2802 extending along the X direction. The pattern 2802 is configured to form an active region (e.g., a fin structure, a well, a protruding structure having alternately stacked silicon and silicon germanium layers, etc., which is sometimes referred to as an oxide diffusion (OD) region) over a substrate. The layout 2800 includes patterns 2804 and 2806 extending along the Y direction. The patterns 2804 to 2806 are each configured to form a gate structure (e.g., a polysilicon gate, a metal gate, etc.) over the active regions. Accordingly, the pattern 2802 may be referred to as an active region, and the patterns 2804 to 2806 may each be referred to as a gate structure.

In some embodiments, each of the gate structures can overlay at least one active region to form a transistor. For example in FIG. 28A, the gate structure 2804, together with the active region 2802, can form the MS 2620 (FIG. 26); and the gate structure 2806, together with the active region 2802, can form the MR 2630. Specifically, the gate structures 2804 and 2806 can operatively serve as gates of the MS 2620 and MR 2630, respectively. Further, the portions of each active region on opposite sides of the overlaying gate structure (i.e., the portions not overlaid by the gate structure) can form the corresponding transistor's source and drain, respectively.

The layout 2800 further includes patterns 2808, 2810, and 2812 extending along the Y direction and disposed between adjacent gate structures (i.e., overlaying the source or drain of a transistor). The patterns 2808 to 2812 are each configured to form a middle-end interconnect structure (sometimes referred to as “MD”). Accordingly, the patterns 2808, 2810, and 2812 may each be referred to as an MD. Such an MD is generally configured to electrically connect the source or drain of a transistor to the source or drain of another transistor or to a supply voltage.

For example, the MD 2808 can connect one source/drain of the MS 2620 to an interconnect structure (formed by pattern 2814, hereinafter interconnect structure 2814) through a via structure 2816. The interconnect structure 2814 may correspond to the WBL shown in FIG. 26, according to some embodiments. The gate structure 2806 (the gate of the MR 2630) may be connected to another interconnect structure (formed by pattern 2830, hereinafter interconnect structure 2830) through a via structure 2818. The interconnect structure 2830 may correspond to the RWL show in FIG. 26, according to some embodiments. The MD 2812 can connect one source/drain of the MR 2630 to yet another interconnect structure (formed by pattern 2832, hereinafter interconnect structure 2832) through a via structure 2820. The interconnect structure 2832 may correspond to the RBL show in FIG. 26, according to some embodiments. The layout 2800 further includes a pattern 2824 extending along the X direction to connect the gate structure 2804 (the gate of the MS 2620) to an component in another device level (e.g., one source/drain of the MW 2610), which will be discussed as follows.

Similarly in FIG. 28B, the layout 2850 includes pattern 2852 extending along the X direction. The pattern 2852 is configured to form an active region (e.g., a fin structure, a well, a protruding structure having alternately stacked silicon and silicon germanium layers, etc., which is sometimes referred to as an oxide diffusion (OD) region) over a substrate. The layout 2850 includes pattern 2854 extending along the Y direction. The pattern 2854 is configured to form a gate structure (e.g., a polysilicon gate, a metal gate, etc.) over the active regions. Accordingly, the pattern 2852 may be referred to as an active region, and the pattern 2854 may be referred to as a gate structure.

In some embodiments, the gate structure 2854, together with the active region 2852, can form the MW 2610 (FIG. 26). Specifically, the gate structure 2854 can operatively serve as a gate of the MW 2610. Further, the portions of each active region on opposite sides of the overlaying gate structure (i.e., the portions not overlaid by the gate structure) can form the corresponding transistor's source and drain, respectively.

The layout 2850 further includes patterns 2856 and 2858 extending along the Y direction and disposed between adjacent gate structures (i.e., overlaying the source or drain of a transistor). The patterns 2856 to 2858 are each configured to form a middle-end interconnect structure (sometimes referred to as “MD”). Accordingly, the patterns 2856 to 2858 may each be referred to as an MD. Such an MD is generally configured to electrically connect the source or drain of a transistor to the source or drain of another transistor or to a supply voltage.

For example, the MD 2856 can connect one source/drain of the MW 2610 to the interconnect structure 2814 (WBL) through a via structure 2860. The MD 2858 can connect the other source/drain of the MW 2610 to the gate structure 2804 (the gate of the MS 2620) disposed in the other device level through a via structure 2862. The gate structure 2854 (the gate of the MW 2610), through a via structure 2864, may be connected to yet another interconnect structure (formed by pattern 2834, hereinafter interconnect structure 2834) that operatively serves as the WWL of FIG. 26.

In some embodiments, the interconnect structures 2830 (RWL), 2832 (RBL), and 2834 (WWL) may be formed in a device level different than the device level formed by the layout 2800 or 2850. For example, the device level having the interconnect structures 2830 to 2834, which can be implemented as one or more metallization layers/levels, can be formed above both the device levels respectively corresponding to the layouts 2800 and 2850. In another example, the device level having the interconnect structures 2830 to 2834, which can be implemented as one or more metallization layers/levels, can be formed between the device levels respectively corresponding to the layouts 2800 and 2850.

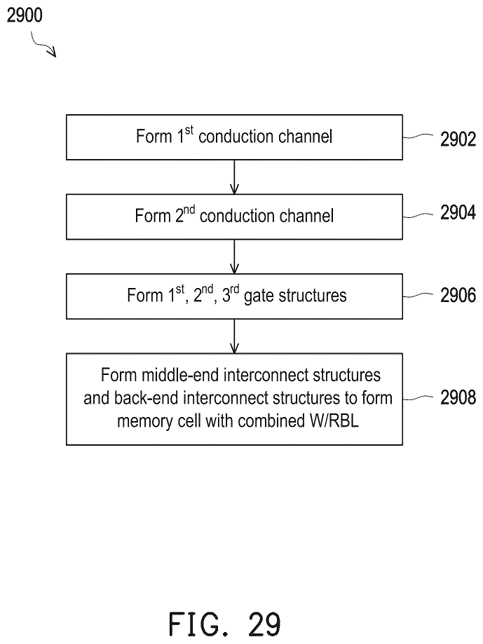

FIG. 29 illustrates a flow chart of an example method 2900 for forming a memory device, in accordance with various embodiments. The memory device, made the method 2900, may include a number of the disclosed memory cells that each have three transistors and a combined W/RBL (e.g., the memory cell 100 of FIG. 1 or the memory cell 200 of FIG. 2). In some embodiments, the method 2900 can form the memory device based on the layout(s) discussed above (e.g., layouts 300, 400, 500, 600). Accordingly, some of the reference numerals used above in the corresponding figures may be used in the following discussion.

While the method 2900 of FIG. 29 is illustrated and described herein as a series of operations, it should be appreciated that the illustrated ordering of such operations is not to be interpreted in a limiting sense. For example, some operations may occur in different orders and/or concurrently with other operations apart from those illustrated and/or described herein. Further, not all illustrated operations may be required to implement one or more aspects or embodiments of the present disclosure herein, and one or more of the operations depicted herein may be carried out in one or more separate operations.

The method 2900 starts with operation 2902 in which one or more first conduction channels (e.g., 410, 420) that have a first conductive type and extend along a first lateral direction are formed in a first area of a substrate. Next, the method 2900 proceeds to operation 2904 in which a second conduction channel (e.g., 430) that has the first conductive type or a second conductive type opposite to the first conductive type and also extends along the first lateral direction is formed in a second area of the substrate.

In some embodiments, the substrate may be a semiconductor substrate, such as a bulk semiconductor, a semiconductor-on-insulator (SOI) substrate, or the like, which may be doped (e.g., with a p-type or an n-type dopant) or undoped. The substrate may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

In some embodiments, each of the first and second conduction channels may be formed as a fin structure or a stack structure having alternating semiconductor layers (e.g., Si and SiGe). The fin/stack structures, in the first and second areas of the substrate, can be formed by patterning the substrate using, for example, photolithography and etching techniques. For example, a mask layer, such as a pad oxide layer and an overlying pad nitride layer, is formed over the substrate. The pad oxide layer may be a thin film comprising silicon oxide formed, for example, using a thermal oxidation process. The pad oxide layer may act as an adhesion layer between the substrate and the overlying pad nitride layer. In some embodiments, the pad nitride layer is formed of silicon nitride, silicon oxynitride, silicon carbo nitride, the like, or combinations thereof. The pad nitride layer may be formed using low-pressure chemical vapor deposition (LPCVD) or plasma enhanced chemical vapor deposition (PECVD), for example.

The method 2900 proceeds to operation 2906 in which at least a first gate structure (e.g., 440), a second gate structure (e.g., 460), and a third gate structure (e.g., 450) are formed over the substrate. In some embodiments, the first to third gate structures can all extend along a second lateral direction perpendicular to the first lateral direction. The first gate structure can overlay the one or more first conduction channels; the second gate structure can also overlay the one or more first conduction channels; and the third gate structure can overlay the second conduction channel. Each of the gate structures, having a metal gate and a high-k gate dielectric, can be formed by a replacement gate process. For example, a number of dummy gate structures, respectively corresponding to the first to third gate structures, can be formed over the substrate, followed by forming a pair of source and drain on opposite sides of each dummy gate structure from the corresponding fin structure. Next, the dummy gate structures may be replaced by the first to third gate structures, respectively.

Upon forming the first to third gate structures (which are sometimes referred to as metal gate structures), three transistors can be formed. For example, the first gate structure and the one or more first conduction channels may operatively form a read transistor (MR) of the memory cell; the second gate structure and the one or more first conduction channels may operatively form a storage transistor (MS) of the memory cell; and the third gate structure and the second conduction channel may operatively form a write transistor (MW) of the memory cell.

The method 2900 proceeds to operation 2908 in which a number of middle-end interconnect structures (e.g., 470, 472, 474, 476, 478, 480) and a number of back-end interconnect structures (e.g., 510, 520, 530, 610, 620, 630) are formed. According to the layout 300 (including 400 to 600), the middle-end interconnect structures are formed to electrically connect the sources/drains of some of the transistors to each other. For example, the middle-end interconnect structure 470 can connect both the respective sources/drains of the transistors MR and MW to each other, which allows them to be connected to a combined W/RBL. Next, the back-end interconnect structures are formed to electrically connect to one or more of the corresponding middle-end interconnect structures. For example, the back-end interconnect structure 510 can connect the middle-end interconnect structure 470 (tying one of the sources/drains of the transistor MR and one of the sources/drains of the transistor MW) to a supply voltage (VDD or GND). Consequently, the memory cell 100 (FIG. 1) or memory cell 200 (FIG. 2) can be formed. The interconnect structures may include a conductive material. The conductive material can include a metal material such as, for example, copper (Cu), aluminum (Al), tungsten (W), or combinations thereof.

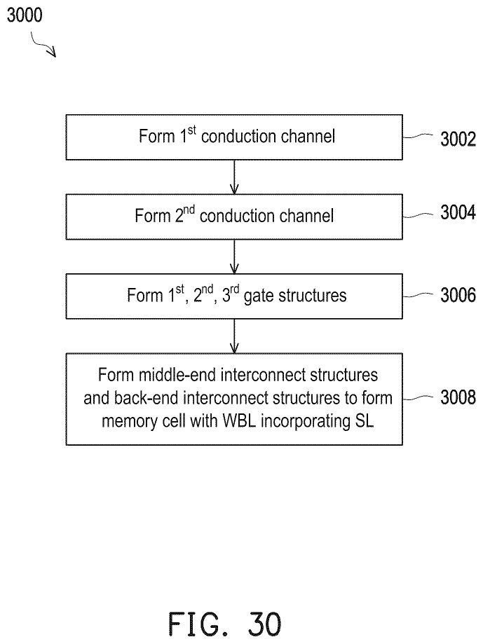

FIG. 30 illustrates a flow chart of an example method 3000 for forming a memory device, in accordance with various embodiments. The memory device, made the method 3000, may include a number of the disclosed memory cells that each have three transistors and a WBL incorporating a SL (e.g., the memory cell 1100 of FIG. 11 or the memory cell 1200 of FIG. 12). In some embodiments, the method 3000 can form the memory device based on the layout(s) discussed above (e.g., layouts 1300, 1400, 1500). Accordingly, some of the reference numerals used above in the corresponding figures may be used in the following discussion.

While the method 3000 of FIG. 30 is illustrated and described herein as a series of operations, it should be appreciated that the illustrated ordering of such operations is not to be interpreted in a limiting sense. For example, some operations may occur in different orders and/or concurrently with other operations apart from those illustrated and/or described herein. Further, not all illustrated operations may be required to implement one or more aspects or embodiments of the present disclosure herein, and one or more of the operations depicted herein may be carried out in one or more separate operations.

The method 3000 starts with operation 3002 in which one or more first conduction channels (e.g., 1310, 1320) that have a first conductive type and extend along a first lateral direction are formed in a first area of a substrate. Next, the method 3000 proceeds to operation 3004 in which a second conduction channel (e.g., 1330) that has the first conductive type or a second conductive type opposite to the first conductive type and also extends along the first lateral direction is formed in a second area of the substrate.

In some embodiments, the substrate may be a semiconductor substrate, such as a bulk semiconductor, a semiconductor-on-insulator (SOI) substrate, or the like, which may be doped (e.g., with a p-type or an n-type dopant) or undoped. The substrate may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

In some embodiments, each of the first and second conduction channels may be formed as a fin structure or a stack structure having alternating semiconductor layers (e.g., Si and SiGe). The fin/stack structures, in the first and second areas of the substrate, can be formed by patterning the substrate using, for example, photolithography and etching techniques. For example, a mask layer, such as a pad oxide layer and an overlying pad nitride layer, is formed over the substrate. The pad oxide layer may be a thin film comprising silicon oxide formed, for example, using a thermal oxidation process. The pad oxide layer may act as an adhesion layer between the substrate and the overlying pad nitride layer. In some embodiments, the pad nitride layer is formed of silicon nitride, silicon oxynitride, silicon carbo nitride, the like, or combinations thereof. The pad nitride layer may be formed using low-pressure chemical vapor deposition (LPCVD) or plasma enhanced chemical vapor deposition (PECVD), for example.

The method 3000 proceeds to operation 3006 in which at least a first gate structure (e.g., 1340), a second gate structure (e.g., 1360), and a third gate structure (e.g., 1350) are formed over the substrate. In some embodiments, the first to third gate structures can all extend along a second lateral direction perpendicular to the first lateral direction. The first gate structure can overlay the one or more first conduction channels; the second gate structure can also overlay the one or more first conduction channels; and the third gate structure can overlay the second conduction channel. Each of the gate structures, having a metal gate and a high-k gate dielectric, can be formed by a replacement gate process. For example, a number of dummy gate structures, respectively corresponding to the first to third gate structures, can be formed over the substrate, followed by forming a pair of source and drain on opposite sides of each dummy gate structure from the corresponding fin structure. Next, the dummy gate structures may be replaced by the first to third gate structures, respectively.

Upon forming the first to third gate structures (which are sometimes referred to as metal gate structures), three transistors can be formed. For example, the first gate structure and the one or more first conduction channels may operatively form a read transistor (MR) of the memory cell; the second gate structure and the one or more first conduction channels may operatively form a storage transistor (MS) of the memory cell; and the third gate structure and the second conduction channel may operatively form a write transistor (MW) of the memory cell.

The method 3000 proceeds to operation 3008 in which a number of middle-end interconnect structures (e.g., 1370, 1372, 1374, 1376, 1378, 1380) and a number of back-end interconnect structures (e.g., 1410, 1420, 1430, 1440, 1510, 1520) are formed. According to the layouts 1300 to 1500, the middle-end interconnect structures are each formed to electrically connect to the source/drain of a corresponding one of the transistors. For example, the middle-end interconnect structure 1372 can connect to one of the sources/drains of the transistor MW and the middle-end interconnect structure 1378 can connect to one of the sources/drains of the transistor MS, which allows them to be connected to each other through a WBL. Next, the back-end interconnect structures are formed to electrically connect to one or more of the corresponding middle-end interconnect structures. For example, the back-end interconnect structure 1440 can connect the middle-end interconnect structures 1372 and 1378 to each other, which may be connected to a supply voltage (VDD or GND). Consequently, the memory cell 1100 (FIG. 11) or memory cell 1200 (FIG. 12) can be formed. The interconnect structures may include a conductive material. The conductive material can include a metal material such as, for example, copper (Cu), aluminum (Al), tungsten (W), or combinations thereof.

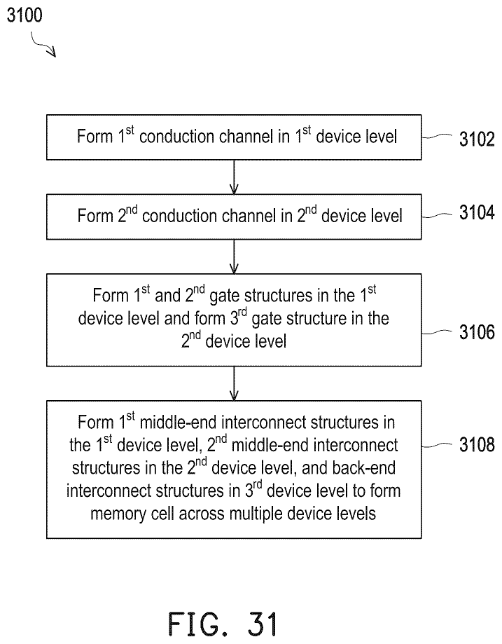

FIG. 31 illustrates a flow chart of an example method 3100 for forming a memory device, in accordance with various embodiments. The memory device, made the method 3100, may include a number of the disclosed memory cells that each have three transistors disposed in two or more device levels (e.g., the memory cell 2000 of FIG. 20, the memory cell 2300 of FIG. 23, or the memory cell 2600 of FIG. 26). In some embodiments, the method 3100 can form the memory device based on the layout(s) discussed above (e.g., layouts 2100 and 2150, 2200 and 2250, 2400 and 2450, 2500 and 2550, 2700 and 2750, 2800 and 2850). Accordingly, some of the reference numerals used above in the corresponding figures may be used in the following discussion.

While the method 3100 of FIG. 31 is illustrated and described herein as a series of operations, it should be appreciated that the illustrated ordering of such operations is not to be interpreted in a limiting sense. For example, some operations may occur in different orders and/or concurrently with other operations apart from those illustrated and/or described herein. Further, not all illustrated operations may be required to implement one or more aspects or embodiments of the present disclosure herein, and one or more of the operations depicted herein may be carried out in one or more separate operations.

The method 3100 starts with operation 3102 in which a first conduction channel (e.g., 2102, 2202, 2402, 2502, 2702, 2802) that has a first conductive type and extends along a first lateral direction are formed in a first device level. Next, the method 3100 proceeds to operation 3104 in which a second conduction channel (e.g., 2152, 2252, 2452, 2552, 2752, 2852) that has the first conductive type or a second conductive type opposite to the first conductive type and also extends along the first lateral direction is formed in a second device level. The first and second device levels, formed over a substrate, may be vertically aligned with respect to each other, according to some embodiments.

In some embodiments, the substrate may be a semiconductor substrate, such as a bulk semiconductor, a semiconductor-on-insulator (SOI) substrate, or the like, which may be doped (e.g., with a p-type or an n-type dopant) or undoped. The substrate may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

In some embodiments, each of the first and second conduction channels may be formed as a fin structure or a stack structure having alternating semiconductor layers (e.g., Si and SiGe). The fin/stack structures, in the first and second areas of the substrate, can be formed by patterning the substrate using, for example, photolithography and etching techniques. For example, a mask layer, such as a pad oxide layer and an overlying pad nitride layer, is formed over the substrate. The pad oxide layer may be a thin film comprising silicon oxide formed, for example, using a thermal oxidation process. The pad oxide layer may act as an adhesion layer between the substrate and the overlying pad nitride layer. In some embodiments, the pad nitride layer is formed of silicon nitride, silicon oxynitride, silicon carbo nitride, the like, or combinations thereof. The pad nitride layer may be formed using low-pressure chemical vapor deposition (LPCVD) or plasma enhanced chemical vapor deposition (PECVD), for example.

The method 3100 proceeds to operation 3106 in which a first gate structure (e.g., 2104, 2204, 2404, 2504, 2704, 2804) and a second gate structure (e.g., 2106, 2206, 2406, 2506, 2706, 2806) are formed over the first conduction channel in the first device level, and a third gate structure (e.g., 2154, 2254, 2454, 2554, 2754, 2854) are formed over the second conduction channel in the second device level. In some embodiments, the first to third gate structures can all extend along a second lateral direction perpendicular to the first lateral direction. The first gate structure can overlay the first conduction channel; the second gate structure can also overlay the first conduction channel; and the third gate structure can overlay the second conduction channel. Each of the gate structures, having a metal gate and a high-k gate dielectric, can be formed by a replacement gate process. For example, a number of dummy gate structures, respectively corresponding to the first to third gate structures, can be formed over the substrate, followed by forming a pair of source and drain on opposite sides of each dummy gate structure from the corresponding fin structure. Next, the dummy gate structures may be replaced by the first to third gate structures, respectively.

Upon forming the first to third gate structures (which are sometimes referred to as metal gate structures), three transistors can be formed. For example, the first gate structure and the one or more first conduction channels may operatively form a read transistor (MR) of the memory cell; the second gate structure and the one or more first conduction channels may operatively form a storage transistor (MS) of the memory cell; and the third gate structure and the second conduction channel may operatively form a write transistor (MW) of the memory cell.

The method 3100 proceeds to operation 3108 in which a number of first middle-end interconnect structures (e.g., 2108, 2110, 2112, 2208, 2210, 2212, 2408, 2410, 2412, 2508, 2510, 2512, 2708, 2710, 2712, 2808, 2810, 2812) are formed in the first device level, a number of second middle-end interconnect structures (e.g., 2156, 2158, 2256, 2258, 2456, 2458, 2556, 2558, 2756, 2758, 2856, 2858) are formed in the second device level, and a number of back-end interconnect structures (e.g., 2130, 2132, 2134, 2136, 2330, 2332, 2334, 2430, 2432, 2434, 2436, 2530, 2532, 2534, 2730, 2732, 2734, 2736, 2830, 2832, 2834, 2836) are formed in a third device level. According to the layouts 2100 to 2850, the middle-end interconnect structures are each formed to electrically connect to the source/drain of a corresponding one of the transistors. Next, the back-end interconnect structures are formed to electrically connect to one or more of the corresponding middle-end interconnect structures. 5 Consequently, the memory cell 2000 (FIG. 20), memory cell 2300 (FIG. 23), or memory cell 2600 (FIG. 26) can be formed. The interconnect structures may include a conductive material. The conductive material can include a metal material such as, for example, copper (Cu), aluminum (Al), tungsten (W), or combinations thereof.

In one aspect of the present disclosure, a semiconductor device is disclosed. The semiconductor device includes a memory cell including a first transistor, a second transistor, and a third transistor. The first transistor has a first gate terminal and the second transistor has a second gate terminal, the first gate terminal and the second gate terminal being connected to a first word line and a second word line, respectively. The first transistor has a pair of first source/drain terminals and the second transistor has a pair of second source/drain terminals, one of the pair of first source/drain terminals and one of the pair of second source/drain terminals being connected to a common bit line. The third transistor has a third gate terminal connected to the other of the pair of first source/drain terminals, and a pair of third source/drain terminals connected to the other of the pair of second source/drain terminals and a supply voltage, respectively.

In another aspect of the present disclosure, a semiconductor device is disclosed. The semiconductor device includes a memory cell comprising one or more first conduction channels extending along a first lateral direction; a first gate structure extending along a second lateral direction and overlaying the one or more first conduction channels; a second gate structure disposed in parallel with the first gate structure and overlaying the one or more first conduction channels; a second conduction channel disposed in parallel with the one or more first conduction channels; a third gate structure extending along the second lateral direction and overlaying the second conduction channel, wherein the third gate structure is aligned with the first gate structure along the second lateral direction; a first interconnect structure extending along the second lateral direction and overlaying both the one or more first conduction channels and the second conduction channel; and a second interconnect structure extending along the second lateral direction and overlaying only the one or more first conduction channels.

In yet another aspect of the present disclosure, a method for forming a memory cell is disclosed. The method includes forming one or more first conduction channels that have a first conductive type and extend along a first lateral direction. The method includes forming a second conduction channel that has the first conductive type or a second conductive type opposite to the first conductive type, and is disposed in parallel with the one or more first conduction channels. The method includes forming a first gate structure that extends along a second lateral direction and overlays the one or more first conduction channels. The method includes forming a second gate structure that is disposed in parallel with the first gate structure and overlays the one or more first conduction channels. The method includes forming a third gate structure that extends along the second lateral direction and overlays the second conduction channel, wherein the third gate structure is aligned with the first gate structure along the second lateral direction. The method includes forming a first interconnect structure that extends along the second lateral direction and overlays both the one or more first conduction channels and the second conduction channel. The method includes forming a second interconnect structure that extends along the second lateral direction and overlays only the one or more first conduction channels.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a memory cell comprising:
one or more first conduction channels extending along a first lateral direction;
a first gate structure extending along a second lateral direction and overlaying the one or more first conduction channels;
a second gate structure disposed in parallel with the first gate structure and overlaying the one or more first conduction channels;
a second conduction channel disposed in parallel with the one or more first conduction channels;
a third gate structure extending along the second lateral direction and overlaying the second conduction channel, wherein the third gate structure is aligned with the first gate structure along the second lateral direction;
a first interconnect structure extending along the second lateral direction and overlaying both the one or more first conduction channels and the second conduction channel; and
a second interconnect structure extending along the second lateral direction and overlaying only the one or more first conduction channels.

2. The memory device of claim 1, wherein the first interconnect structure operatively serves as a write/read bit line of the memory cell, and the second interconnect structure is tied to a supply voltage.

3. The memory device of claim 2, wherein a voltage applied to the write/read bit line is configured to change according to a logic state to be written to the second gate structure.

4. The memory device of claim 2, wherein a voltage presented on the write/read bit line is configured to change according to a logic state stored in the second gate structure.

5. The memory device of claim 1, wherein the one or more first conduction channels and the second conduction channel have a same conductive type.

6. The memory device of claim 1, wherein the one or more first conduction channels have a first conductive type, and the second conduction channel has a second conductive type opposite to the first conductive type.

7. The memory device of claim 1, wherein the memory cell further comprises:
a third interconnect structure extending along the second lateral direction and disposed opposite the third gate structure from the first interconnect structure; and
a fourth interconnect structure extending along the first lateral direction and configured to couple the third interconnect structure to the second gate structure.

8. A method for forming a memory cell, comprising:
forming one or more first conduction channels that have a first conductive type and extend along a first lateral direction;
forming a second conduction channel that has the first conductive type or a second conductive type opposite to the first conductive type, and is disposed in parallel with the one or more first conduction channels;
forming a first gate structure that extends along a second lateral direction and overlays the one or more first conduction channels;
forming a second gate structure that is disposed in parallel with the first gate structure and overlays the one or more first conduction channels;
forming a third gate structure that extends along the second lateral direction and overlays the second conduction channel, wherein the third gate structure is aligned with the first gate structure along the second lateral direction;
forming a first interconnect structure that extends along the second lateral direction and overlays both the one or more first conduction channels and the second conduction channel; and
forming a second interconnect structure that extends along the second lateral direction and overlays only the one or more first conduction channels.

9. The method of claim 8, wherein the first interconnect structure operatively serves as a bit line configured to read and write a memory cell formed by the one or more first conduction channels, the second conduction channel, the first gate structure, the second gate structure, and the third gate structure, while the second interconnect structure is tied to a supply voltage.

10. The method of claim 8, wherein the one or more first conduction channels and the second conduction channel are formed to have the first conductive type.

11. The method of claim 8, wherein the one or more first conduction channels are formed to have the first conductive type, and wherein the second conduction channel is formed to have the second conductive type opposite to the first conductive type.

12. The method of claim 8, further comprising:
forming a third interconnect structure extending along the second lateral direction and disposed opposite the third gate structure from the first interconnect structure.

13. The method of claim 12, further comprising:
forming a fourth interconnect structure extending along the first lateral direction and configured to couple the third interconnect structure to the second gate structure.

14. The method of claim 8, wherein forming the first gate structure comprises:
forming a gate dielectric structure; and
forming a gate metal structure.

15. A memory device, comprising:
a memory cell comprising:
a pair of first transistors defined by a pair of first conduction channels, a first gate structure overlaying the pair of first conduction channels, and a second gate structure overlaying the pair of first conduction channels;
a second transistor defined by a second conduction channel disposed in parallel with the pair of first conduction channels and a third gate structure overlaying the second conduction channel; and
a third transistor defined by the second conduction channel and the second gate structure overlaying the second conduction channel.

16. The memory device of claim 15, further comprising a first interconnect structure disposed in parallel with the first gate structure the second gate structure, wherein the first interconnect structure is coupled to the pair of first conduction channels.

17. The memory device of claim 16, further comprising a second interconnect structure coupled to a portion of the second conduction channel corresponding to the second transistor and the third transistor.

18. The memory device of claim 17, further comprising a metal layer coupled to the second interconnect structure and the second gate structure.

19. The memory device of claim 15, wherein a voltage applied to the second transistor is configured to change according to a logic state to be written to via the second gate structure.

20. The memory device of claim 15, wherein a voltage applied to the third transistor is configured to change according to a logic state via the second transistor.
